(19) United States
(12) Patent Application Publication
(10) Pub. No.: US 2026/0334017 A1
(43) Pub. Date: Oct. 22, 2026

(54) ORGANIC ELECTRO-LUMINESCENCE DISPLAY DEVICE AND METHOD FOR MANUFACTURING ORGANIC ELECTRO-LUMINESCENCE DISPLAY DEVICE

(71) Applicant: Japan Display Inc., Tokyo (JP)

(72) Inventor: Tatsuya ISHII, Tokyo (JP)

(21) Appl. No.: 19/570,932

(22) Filed: Mar. 18, 2026

(30) Foreign Application Priority Data
Apr. 22, 2025 (JP) 2025-070457

(51) Int. Cl. H10K 59/122; H10K 59/12

(52) U.S. Cl. CPC H10K 59/122; H10K 59/1201

(57) ABSTRACT

Each of the plurality of pixels of an organic electro-luminescence display device includes a first electrode, a first insulating layer, a second electrode including a first part and a second part, an opening part including a first bottom part exposing the surface of the first electrode, a third electrode in contact with the first electrode, an electro-luminescence element arranged on the first part, a second insulating layer arranged among the electro-luminescence element, the first part, the first insulating layer and the third electrode, on the third electrode and the opening part, and on the second part, and a first groove including a second bottom part extending to the side surface of the second insulating layer and exposing the surface of the third electrode, wherein the first bottom part is arranged in a position deeper from the top surface of the second insulating layer than the second bottom part.

### CROSS-REFERENCE TO RELATED APPLICATIONS

This application claims the benefit of priority to Japanese Patent Application No. 2025-070457 filed on April 22, 2025, the entire contents of which are incorporated herein by reference.

### FIELD

An embodiment of the present invention relates to an organic electro-luminescence display device and a method for manufacturing the organic electro-luminescence display device.

### BACKGROUND

In recent years, a display device (hereinafter, referred to as an “organic EL display device”) in which a pixel including an organic electro-luminescence element (hereinafter, referred to as an “organic EL element”) is formed has been mounted on a smart phone, a camera, or the like. For example, a manufacturing process of the organic EL display device includes forming an organic EL element according to the color to be emitted by a vacuum-deposition method, an ink-jet method, or the like. For example, it is known that the organic EL elements according to the color to be emitted are formed to be spaced apart from each other by minute grooves.

### SUMMARY

An organic electro-luminescence display device includes a plurality of pixels arranged in a first direction and a second direction intersecting the first direction, each of the plurality of pixels includes a first electrode; a first insulating layer arranged on the first electrode; a first inorganic insulating layer arranged on the first insulating layer; a second electrode arranged on the first insulating layer, and including a first part provided apart from the first inorganic insulating layer and a second part overlapping and in contact with the first inorganic insulating layer; an opening part arranged in the first insulating layer and the first inorganic insulating layer, and including a side surface of the first inorganic insulating layer, a side surface of the first insulating layer, and a first bottom part extending to the side surface of the first insulating layer and exposing a part of the surface of the first electrode; a third electrode arranged on the first inorganic insulating layer, and in contact with the first inorganic insulating layer, the side surface of the first inorganic insulating layer, the side surface of the first insulating layer, and the first electrode at the first bottom part; an electro-luminescence element arranged on and in contact with the first part; a second insulating layer arranged above the electro-luminescence element, the first part, the first insulating layer excluding an area where the first part and the first inorganic insulating layer are provided, between the first inorganic insulating layer except an area where the third electrode is provided and the third electrode, on the third electrode and the opening part, and on the second part excluding an area where the third electrode is provided; a first groove arranged in the second insulating layer, and including a side surface of the second insulating layer and a second bottom part extending to the side surface of the second insulating layer and exposing a part of the surface of the third electrode; and a fourth electrode arranged on the electro-luminescence element and in contact with the electro-luminescence element, the side surface of the second insulating layer, and the third electrode at the second bottom part; wherein the first bottom part is arranged in a position deeper from the top surface of the second insulating layer than the second bottom part.

A method for manufacturing an organic electro-luminescence display device including plurality of pixels arranged in a first direction and a second direction intersecting the first direction, each of the plurality of pixels includes a first electrode; a first insulating layer arranged on the first electrode; a first inorganic insulating layer arranged on the first insulating layer; a second electrode arranged on the first insulating layer, and including a first part provided apart from the first inorganic insulating layer and a second part overlapping and in contact with the first inorganic insulating layer; an opening part arranged in the first insulating layer and the first inorganic insulating layer, and including a side surface of the first inorganic insulating layer, a side surface of the first insulating layer, and a first bottom part extending to the side surface of the first insulating layer and exposing a part of the surface of the first electrode; a third electrode arranged on the first inorganic insulating layer, and in contact with the first inorganic insulating layer, the side surface of the first inorganic insulating layer, the side surface of the first insulating layer, and the first electrode at the first bottom part; an electro-luminescence element arranged on and in contact with the first part; a second insulating layer arranged above the electro-luminescence element, the first part, the first insulating layer excluding an area where the first part and the first inorganic insulating layer are provided, between the first inorganic insulating layer except an area where the third electrode is provided and the third electrode, on the third electrode and the opening part, and on the second part excluding an area where the third electrode is provided; a first groove arranged in the second insulating layer, and including a side surface of the second insulating layer and a second bottom part extending to the side surface of the second insulating layer and exposing a part of the surface of the third electrode; and a fourth electrode arranged on the electro-luminescence element and in contact with the electro-luminescence element, the side surface of the second insulating layer, and the third electrode at the second bottom part, and the first bottom part is arranged in a position deeper from the top surface of the second insulating layer than the second bottom part. The method includes forming a second inorganic insulating layer on the second electrode where the second insulating layer is not arranged and on the second insulating layer; forming a third inorganic insulating layer on the second inorganic insulating layer overlapping a part of the third electrode and the second insulating layer; forming a fourth inorganic insulating layer on the second inorganic insulating layer where the third inorganic insulating layer is not provided and on the side surface and top surface of the third inorganic insulating layer; forming a sidewall by removing the fourth inorganic insulating layer on the second inorganic insulating layer where the third inorganic insulating layer is not provided, the fourth inorganic insulating layer on the top surface, and a part of the fourth inorganic insulating layer on the side surfaces; and forming the first groove using the sidewall.

### BRIEF DESCRIPTION OF DRAWINGS

FIG. 1 is a plan view showing a configuration of an organic EL display device according to a first embodiment.

FIG. 2 is a layout diagram showing an example of a configuration of a pixel according to the first embodiment.

FIG. 3 is a cross-sectional view showing an example of a cross-sectional structure of a pixel according to the first embodiment.

FIG. 4 is a cross-sectional view showing a structure of a cross-section taken along a line A1-A2 of a pixel shown in FIG. 2.

FIG. 5 is a cross-sectional view showing a structure of a cross-section taken along a line B1-B2 of a pixel shown in FIG. 2.

FIG. 6A is a sequence diagram showing a method for manufacturing an organic EL display device according to a second embodiment.

FIG. 6B is a sequence diagram showing a method for manufacturing an organic EL display device according to the second embodiment.

FIG. 7 is a cross-sectional view showing a structure of a cross-section taken along a line A1-A2 of a pixel according to the second embodiment.

FIG. 8 is a cross-sectional view showing a structure of a cross-section taken along a line A1-A2 of a pixel according to the second embodiment.

FIG. 9 is a cross-sectional view showing a structure of a cross-section taken along a line A1-A2 of a pixel according to the second embodiment.

FIG. 10 is a cross-sectional view showing a structure of a cross-section taken along a line A1-A2 of a pixel according to the second embodiment.

FIG. 11 is a cross-sectional view showing a structure of a cross-section taken along a line A1-A2 of a pixel according to the second embodiment.

FIG. 12 is a cross-sectional view showing a structure of a cross-section taken along a line A1-A2 of a pixel according to the second embodiment.

FIG. 13 is a cross-sectional view showing a structure of a cross-section taken along a line A1-A2 of a pixel according to the second embodiment.

FIG. 14 is a cross-sectional view showing a structure of a cross-section taken along a line A1-A2 of a pixel according to the second embodiment.

FIG. 15 is a cross-sectional view showing a structure of a cross-section taken along a line A1-A2 of a pixel according to the second embodiment.

FIG. 16 is a cross-sectional view showing a structure of a cross-section taken along a line A1-A2 of a pixel according to the second embodiment.

FIG. 17 is a cross-sectional view showing a structure of a cross-section taken along a line A1-A2 of a pixel according to the second embodiment.

FIG. 18 is a cross-sectional view showing a structure of a cross-section taken along a line A1-A2 of a pixel according to the second embodiment.

FIG. 19 is a cross-sectional view showing a structure of a cross-section taken along a line A1-A2 of a pixel according to the second embodiment.

FIG. 20 is a layout diagram showing an example of a configuration of a pixel according to a third embodiment.

FIG. 21 is a layout diagram showing an example of a configuration of a pixel according to the third embodiment.

FIG. 22 is a layout diagram showing an example of a configuration of a pixel according to the third embodiment.

FIG. 23 is a cross-sectional view showing a structure of a cross-section taken along a line C1-C2 of a pixel shown in FIG. 22.

### DESCRIPTION OF EMBODIMENTS

Hereinafter, embodiments of the present invention will be described with reference to the drawings and the like. However, the present invention can be implemented in many different ways and is not limited to the description of the embodiments exemplified below. For clarity of explanation, the drawings may be schematically represented in terms of width, thickness, shape, and the like of respective portions as compared with actual embodiments, but the drawings are merely examples, and do not limit the interpretation of the present invention. Furthermore, in the present specification and drawings, elements similar to those previously described with respect to the preceding figures may be denoted by the same reference signs or numbers followed by a letter, such as a, b, A, B, or by a number followed by a hyphen and a number, and detailed descriptions may be omitted as appropriate. In addition, the terms “first” and “second” appended to each element are convenient labels used to distinguish each element and have no further meaning unless specifically explained.

In the case where a member or region is to be “on (or under)” another member or region in the present specification, unless otherwise specified, this includes not only the case where it is directly above (or below) the other member or region, but also the case where it is above (or below) the other member or region, that is, it also includes the case where another component is included above (below) the other member or region.

In the present specification, a first direction D1 intersects a second direction D2, and a third direction D3 intersects the first direction D1 and the second direction D2 (a direction corresponding to a normal direction to a D1-D2 plane). For example, the first direction D1, the second direction D2, and the third direction D3 correspond to a direction X (direction x), a direction Y (direction y), and a direction Z (direction z).

In the present specification, when the terms identical, same, and coincident are used, identical, same, and coincident may include tolerances within the design range.

In the present specification, when elements of an organic EL display device 100 having the same reference signs are to be distinguished from one another, letters are added after the reference signs of the elements having the same reference signs.

### First Embodiment

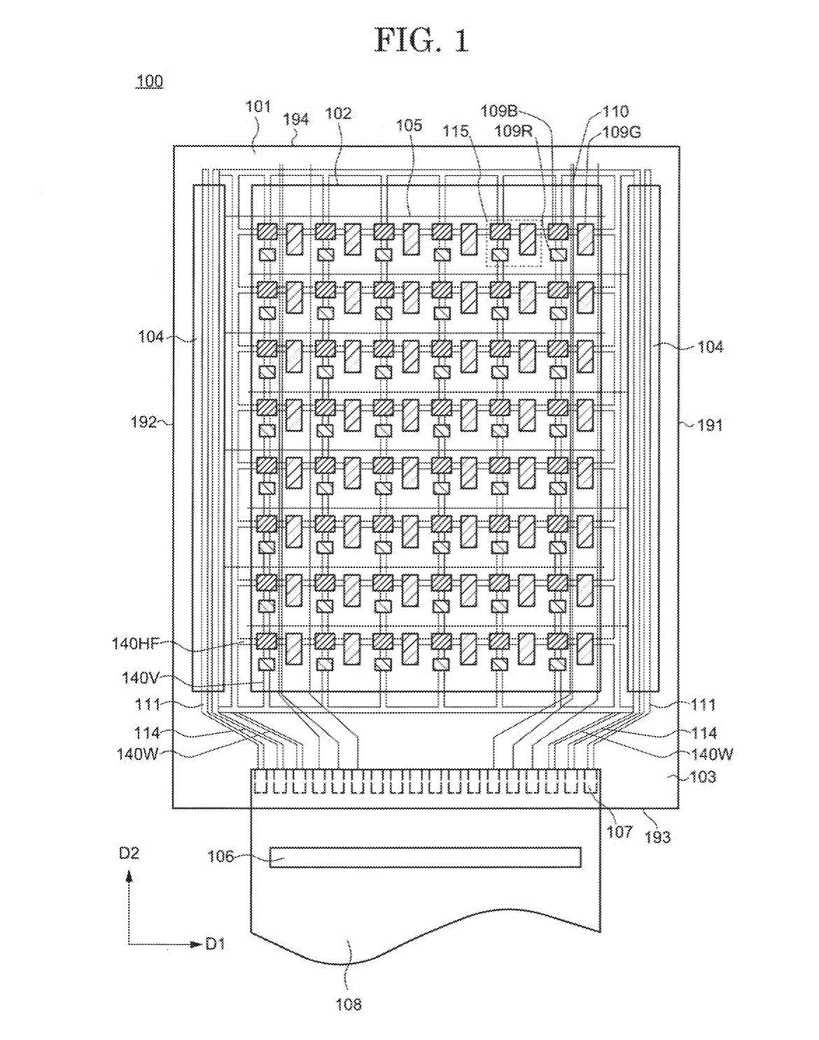

An overview of the organic EL display device 100 will be described with reference to FIG. 1 to FIG. 5.

### Configuration of Organic EL Display Device 100

FIG. 1 is a schematic diagram showing a configuration of the organic EL display device 100.

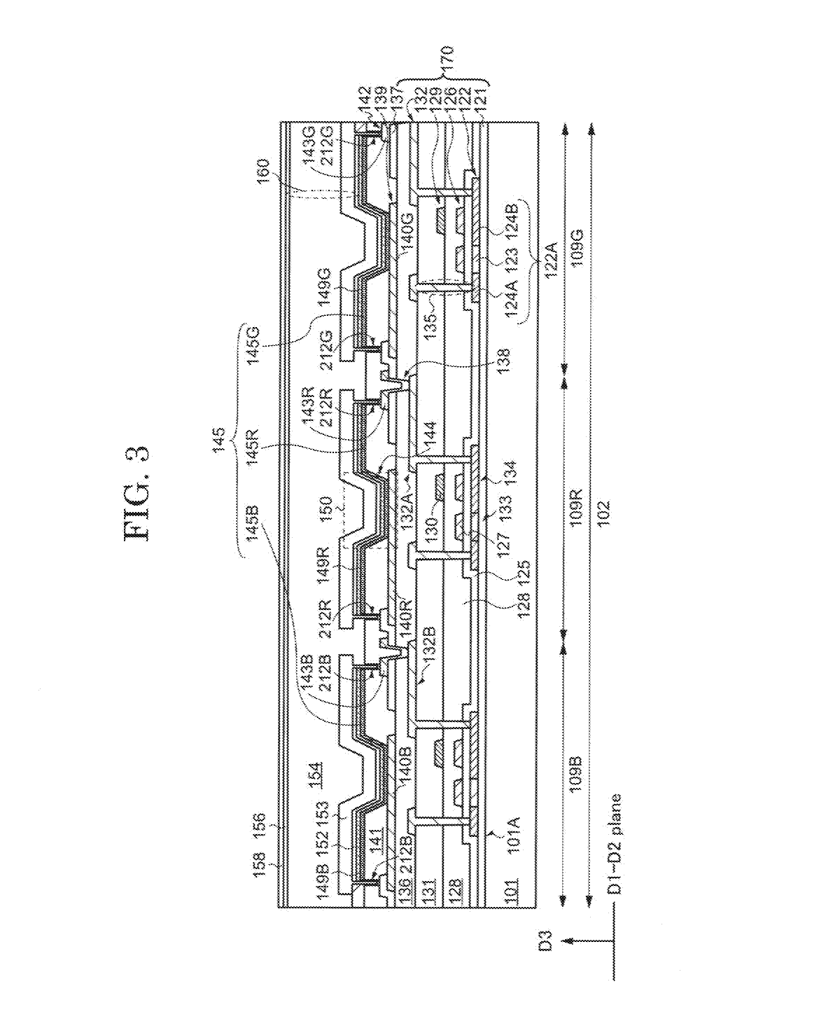

For example, as shown in FIG. 1, the organic EL display device 100 includes a display section 102 and a peripheral section 103 formed on a first surface 101A (see FIG. 3) of a substrate 101. The organic EL display device 100 is surrounded by a first side 191, a second side 192 opposed to the first side, a third side 193, and a fourth side 194 opposed to the third side in a plan view. The peripheral section 103 surrounds the display section 102. In the peripheral section 103, a scanning signal line drive circuit 104 is arranged in a vicinity of the first side 191 and in a vicinity of the second side 192, and a terminal section is arranged in a vicinity of the third side 193. The terminal section includes a plurality of terminals 107. The plurality of terminals 107 is arranged along the first direction D1 (row direction) and is arranged on a lower side of the display section 102 along the second direction D2 (column direction). A plurality of pixels 115 is arranged in the display section 102.

A flexible printed circuit board 108 is connected to the terminal section (the plurality of terminals 107). A driver IC 106 is arranged on the flexible printed circuit board 108 using a COF (Chip on Film) method. The driver IC 106 may be arranged on the flexible printed circuit board 108 using a COG (Chip on Glass) method.

For example, the driver IC 106 may include a video signal line drive circuit. In the present embodiment, the driver IC 106 or the scanning signal line drive circuit 104 may be individually referred to as a control circuit or a control section, and the driver IC 106 and the scanning signal line drive circuit 104 may be collectively referred to as a control circuit or a control section.

A plurality of scanning signal lines 105 is connected to the scanning signal line drive circuit 104. The plurality of scanning signal lines 105 extends in the first direction D1 with respect to the display unit 102 and is arranged along an imaginary line parallel to the second direction D2. The scanning signal line drive circuit 104 is arranged on the first side 191 side and the second side 192 side with respect to the display unit 102. The plurality of scanning signal lines 105 is electrically connected to the plurality of pixels 115. For example, a plurality of video signal lines 110, a common electrode line 140W, a high-potential power supply line 111, and a low-potential power supply line 114 are connected to the plurality of terminals 107. The plurality of video signal lines 110 is arranged to extend in the second direction D2 of the organic EL display device 100. The plurality of video signal lines 110 is electrically connected to the plurality of pixels 115, and is electrically connected to the driver IC 106 via the plurality of terminals 107 and the flexible printed circuit board 108. The common electrode line 140W is electrically connected to a plurality of common electrode lines 140V extending in the second direction D2 and arranged along an imaginary line parallel to the first direction D1, and a plurality of common electrode lines 140HF extending in the first direction D1 and arranged along an imaginary line parallel to the second direction D2. In addition, the plurality of common electrode lines 140V and the plurality of common electrode lines 140HF are provided in a lattice pattern and are electrically connected to a common electrode 140 in each pixel 115. In addition, for example, the common electrode line 140W, the plurality of common electrode lines 140V, and the plurality of common electrode lines 140HF are electrically connected to the low-potential power supply line 114 in the peripheral section 103. The high-potential power supply line 111 and the low-potential power supply line 114 are electrically connected to the scanning signal line drive circuit 104. The high-potential power supply line 111 and the low-potential power supply line 114 may be electrically connected to the plurality of pixels 115.

The driver IC 106 supplies a signal (voltage) to the scanning signal line drive circuit 104, the plurality of video signal lines 110, the high-potential power supply line 111, and the low-potential power supply line 114. The plurality of scanning signal lines 105 supplies scanning signals corresponding to the respective plurality of pixels 115 to the plurality of pixels 115. The plurality of video signal lines 110 supplies video signals from the driver IC 106 according to the video displayed on the plurality of pixels 115. The common electrode line 140W, the high-potential power supply line 111, and the low-potential power supply line 114 supply potentials to the scanning signal line drive circuit 104 and the plurality of pixels 115.

### 1-2. Configuration of Pixel 115

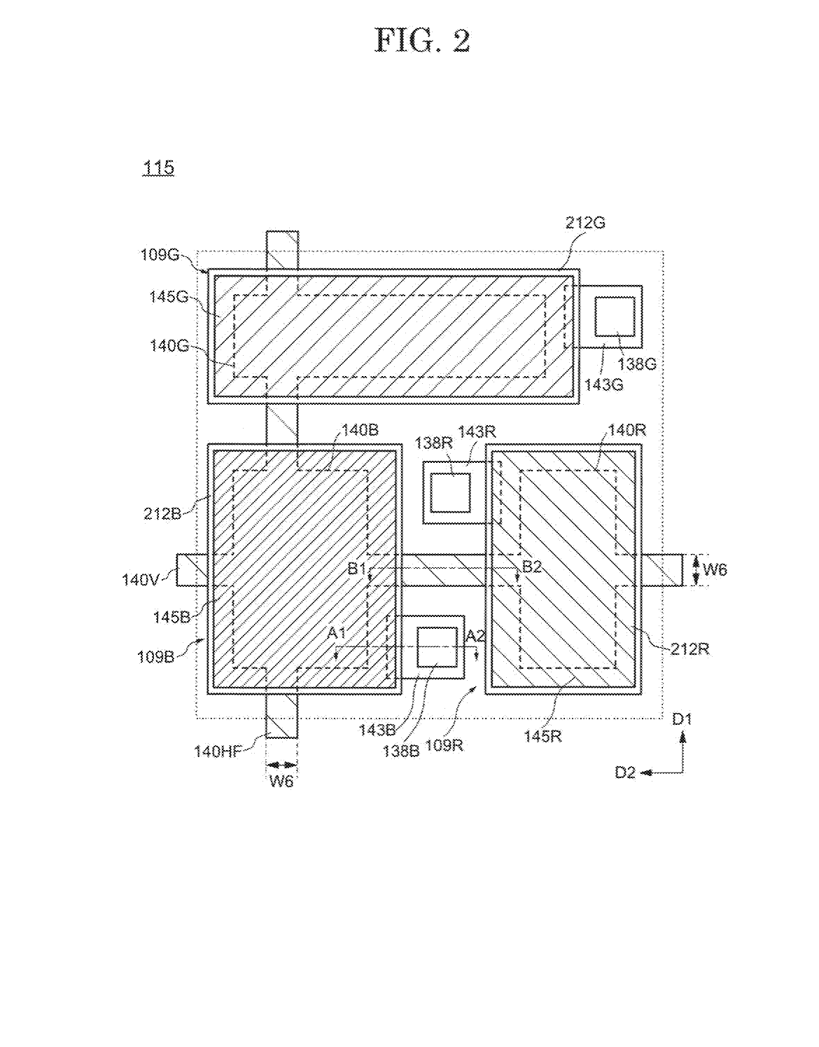

FIG. 2 is a layout diagram showing an example of a configuration of the pixel 115 included in the organic EL display device 100. The pixel 115 is shown by a dashed line in FIG. 1 and FIG. 2. The dashed line is an imaginary line for simply showing a region of the pixel 115.

As shown in FIG. 1, the plurality of pixels 115 is arranged in a matrix in the first direction D1 and the second direction D2. The pixel 115 includes a sub-pixel 109R, a sub-pixel 109G, and a sub-pixel 109B. For example, the sub-pixel 109R and the sub-pixel 109B are arranged side by side in the second direction D2. The sub-pixel 109B and the sub-pixel 109G and the sub-pixel 109R and the sub-pixel 109G are arranged side by side in the first direction D1. A plurality of sub-pixels 109G is arranged side by side in the second direction D2. That is, in the display section 102, a column in which the sub-pixel 109B and the sub-pixel 109R are alternately arranged along the second direction D2 and a column in which only the sub-pixel 109G is arranged along the second direction D2 are alternately arranged in the first direction D1 (row direction).

A light-emitting layer 145R, a light-emitting layer 145G, and a light-emitting layer 145B shown in FIG. 2 emit different colors from each other. As shown in FIG. 2, the layout of the pixel 115 includes the sub-pixel 109R, the sub-pixel 109G, and the sub-pixel 109B. The sub-pixel 109R includes an opening 138R, a pixel electrode 143R electrically connected to the opening 138R, a common electrode 140R, a groove 212R, and the light-emitting layer 145R. Similar to the sub-pixel 109R, the sub-pixel 109G includes an opening 138G, a pixel electrode 143G electrically connected to the opening 138G, a common electrode 140G, a groove 212G, and the light-emitting layer 145G, and the sub-pixel 109B includes an opening 138B, a pixel electrode 143B electrically connected to the opening 138B, a common electrode 140B, a groove 212B, and the light-emitting layer 145B. In addition, the common electrode 140R, the common electrode 140G, and the common electrode 140B are electrically connected by the common electrode lines 140HF and 140V. The width of each of the common electrode lines 140HF and 140V is a width W6. The pixel 115 includes elements other than those described above, but the elements other than those described above are omitted in FIG. 2. The groove 212 may be referred to as a first groove.

For example, the light-emitting layer 145R is a light-emitting element that emits red light, the light-emitting layer 145G is a light-emitting element that emits green light, and the light-emitting layer 145B is a light-emitting element that emits blue light. In the present embodiment, components including a light-emitting element that emits red light are indicated by R (red), components including a light-emitting element that emits green light are indicated by G (green), and components including a light-emitting element that emits blue light are indicated by B (blue).

For example, an emission peak wavelength of the light-emitting element that emits blue light is 460 nm or more and 500 nm or less, an emission peak wavelength of the light-emitting element that emits green light is 500 nm or more and 570 nm or less, and an emission peak wavelength of the light-emitting element that emits red light is 610 nm or more and 780 nm or less.

### 1-3. Cross-section of Organic EL Display Device 100

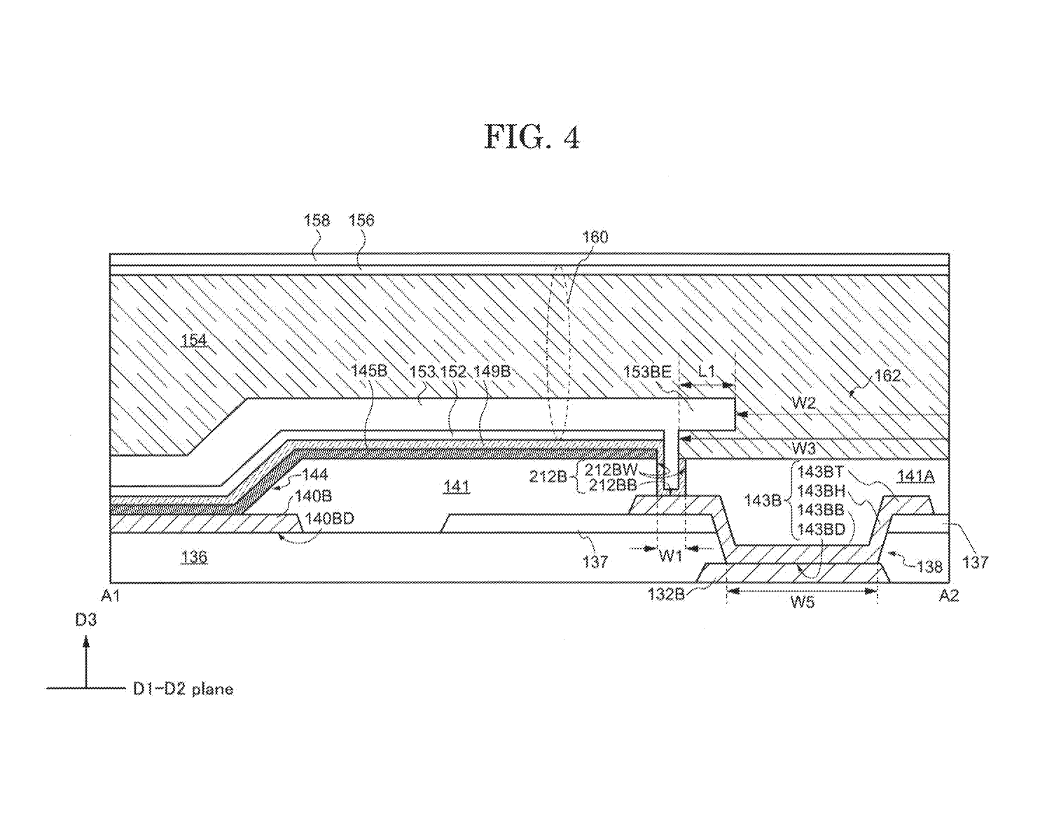

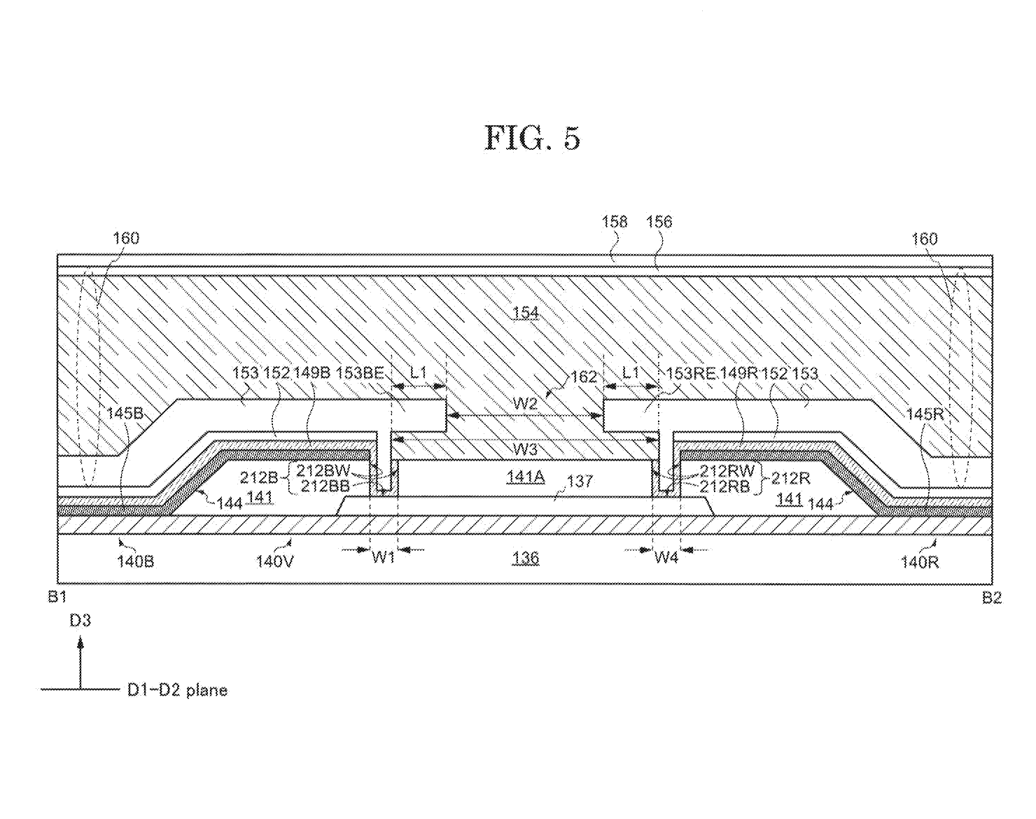

FIG. 3 is a cross-sectional view showing an example of a cross-sectional structure of the organic EL display device 100 shown in FIG. 1, and FIG. 4 is a cross-sectional view showing an example of a structure of a cross-section taken along a line A1-A2 shown in FIG. 2. FIG. 5 is a cross-sectional view showing an example of a structure of a cross-section taken along a line B1-B2 shown in FIG. 2. Configurations that are the same as or similar to those in FIG. 1 and FIG. 2 will be described as necessary.

As shown in FIG. 3, a semiconducting layer 122 is provided on the first surface 101A of the substrate 101 via an underlayer 121. The semiconductor layer 122 includes a channel section 123, a source section 124A, and a drain section 124B. The source and drain functions of the source section 124A and the drain section 124B may be switched depending on the voltage supplied to each of them.

A gate insulating layer 125, a conductive layer 126, an insulating layer 128, a conductive layer 129, an insulating layer 131, and a conductive layer 132 are provided in this order on the semiconductor layer 122. The conductive layer 126 includes a gate electrode 127 and the scanning signal line 105 (see FIG. 1). The conductive layer 129 includes a capacitance line 130. The conductive layer 132 includes an electrode 132A, an electrode 132B, the high-potential power supply line 111, the low-potential power supply line 114, and the video signal line 110 (see FIG. 1). The conductive layer 132 may be referred to as a first electrode.

The organic EL display device 100 includes a plurality of transistors. Each of the plurality of transistors is formed using a semiconductor layer 122A (the channel section 123, the source section 124A, and the drain section 124B), the gate insulating layer 125, and the gate electrode 127. The channel section 123 is a region where the semiconductor layer 122 and the gate electrode 127 overlap each other, and is a region provided between the source section 124A and the drain section 124B. The plurality of transistors includes a transistor 133. The transistor 133 is included in the sub-pixel 109R, the sub-pixel 109G, and the sub-pixel 109B, and is a transistor for driving the sub-pixel 109R, the sub-pixel 109G, and the sub-pixel 109B.

In addition, the organic EL display device 100 may include capacitance elements. For example, a capacitive element 134 is formed using the capacitance line 130 and the semiconductor layer 122 with the gate insulating layer 125 as a dielectric. In addition, the capacitive element 134 may be formed using the capacitance line 130 and the conductive layer 126 with the insulating layer 128 as a dielectric, and may be formed using the capacitance line 130 and the conductive layer 132 with the insulating layer 131 as a dielectric. Furthermore, the capacitive element 134 may be formed using the capacitance line 130 and a layer above the capacitance line 130.

An opening 135 reaching the semiconductor layer 122 is provided in the gate insulating layer 125, the insulating layer 128, and the insulating layer 131. The conductive layer 132 is electrically connected to the semiconductive layer 122, the source section 124A, and the drain section 124B through the opening 135. In addition, an opening (not shown) reaching the gate electrode 127 is also provided in the insulating layer 128 and the insulating layer 131, and an opening (not shown) reaching the capacitance line 130 is also provided in the insulating layer 128 and the insulating layer 131.

An insulating layer 136 is provided to cover the conductive layer 132. The insulating layer 136 may be referred to as a first insulating layer.

For example, an array layer 170 includes elements that form a transistor, and includes the underlayer 121 to an insulating layer 137.

Each element above a conductive layer 139 will be described with reference to FIG. 4 and FIG. 5. Since the sub-pixels 109R, 109G, and 109B include a similar configuration to each other, the configuration of the sub-pixel 109B will be described in the following description of the organic EL display device 100, and the configurations of the sub-pixels 109G and 109R will be described as necessary.

The conductive layer 139 is provided on the insulating layer 136. The conductive layer 139 includes the common electrode 140, the common electrode line 140W (see FIG. 2), the common electrode line 140HF (see FIG. 2), the common electrode line 140V, the common electrode 140B, the common electrode 140G (see FIG. 3), and the common electrode 140R. For example, the common electrode 140B shown in FIG. 4 includes a lower surface 140BD of a bottom portion. The lower surface 140BD of the bottom portion is in contact with the insulating layer 136. In addition, as shown in FIG. 5, the common electrode 140B is electrically connected to the common electrode line 140V and electrically connected to the common electrode 140R in the adjacent sub-pixel 109R. Similar to the lower surface 140BD of the bottom portion in the common electrode 140B, the lower surface of the bottom portion of the common electrode line 140V and the lower surface of the bottom portion of the common electrode 140R are in contact with the insulating layer 136. The common electrode 140 (the common electrode 140, the common electrode line 140W, the common electrode line 140HF, common electrode line 140V, the common electrode 140B, the common electrode 140G, and the common electrode 140R) may be referred to as a second electrode. In addition, the common electrode 140, the common electrode 140B, the common electrode 140G, and the common electrode 140R in the conductive layer 139 may be referred to as a first part, and the common electrode line 140W, the common electrode line 140HF, and the common electrode line 140V among the conductive layer 139 may be referred to as a second part. In addition, the common electrode 140G and the common electrode 140R have a configuration similar to that of the common electrode 140B.

The insulating layer 137 is provided on the insulating layer 136 to be in contact with the insulating layer 136 and provided to be in contact with the conductive layer 139 provided on the insulating layer 136. Specifically, as shown in FIG. 4, the insulating layer 137 is provided to be spaced apart from the common electrode 140B and to be in contact with the insulating layer 136 as the same layer as the common electrode 140B, and as shown in FIG. 5, the insulating layer 137 is provided on the common electrode line 140V electrically connected to the common electrode 140B and the common electrode 140R to be in contact with the common electrode line 140V. The insulating layer 137 may be referred to as a first inorganic insulating layer.

A plurality of openings 138 is provided in the insulating layer 136 and the insulating layer 137. The opening 138 includes the opening 138B, the opening 138G (see FIG. 2), and the opening 138R (see FIG. 2). For example, as shown in FIG. 4, the opening 138B exposes sidewalls of the insulating layer 137, sidewalls of the insulating layer 136, and a part of the surface of the conductive layer 132 (the electrode 132B). Therefore, the opening 138 includes a first bottom part that exposes a part of the surface of the conductive layer 132 (for example, the electrode 132A shown in FIG. 3 and the electrode 132B shown in FIG. 4). Although not shown, the opening 138 exposes a part of the terminal 107. The exposed part of the terminal 107 is connected to the flexible printed circuit board 108 using a conductive film such as an anisotropic conductive film (not shown). In addition, the opening 138G and the opening 138R have a configuration similar to that of the opening 138B.

A conductive layer 142 is provided to be in contact with a part of the upper surface of the insulating layer 137, a part of the surface of the conductive layer 132 (for example, the electrode 132B shown in FIG. 4) exposed by the opening 138, the sidewalls of the insulating layer 136, and the sidewalls of the insulating layer 137. In other words, the conductive layer 142 is provided to be in contact with a part of the upper surface of the insulating layer 137 and the opening 138. The conductive layer 142 includes a pixel electrode 143. The pixel electrode 143 includes the pixel electrode 143B, the pixel electrode 143G (see FIG. 3), and the pixel electrode 143R (see FIG. 3). For example, as shown in FIG. 4, the pixel electrode 143B includes a flat portion 143BT, an inclined portion 143BH continuous with the flat portion 143BT, a bottom portion 143BB continuous with the flat portion 143BT and the inclined portion 143BH, and a lower surface 143BD of the bottom portion 143BB. The flat portion 143BT is in contact with the upper surface of the insulating layer 137, the inclined portion 143BH is in contact with the sidewalls of the insulating layer 137 and the sidewalls of the insulating layer 136, and the bottom portion 143BB (the lower surface 143BD) is in contact with a part of the surface of the electrode 132B exposed by the opening 138 (the opening 138B). Therefore, the opening 138 (the opening 138B) electrically connects the common electrode 140 and the conductive layer 132 (the electrode 132B). In addition, the pixel electrode 143G and the pixel electrode 143R have a configuration similar to that of the pixel electrode 143B. The common electrode 140 (the conductive layer 139) may be referred to as a third electrode.

An insulating layer 141 is provided to cover the surface (upper surface) and end portions of the common electrode 140, the surface (upper surface) and end portions of the insulating layer 137, and the pixel electrode 143. The insulating layer 141 includes an insulating layer 141A, and the insulating layer 141A is provided on the surface (upper surface) and end portions of the pixel electrode 143. In addition, the insulating layer 141 includes the grooves 212R, 212G, and 212B (see FIG. 2 and FIG. 3). The groove 212 is provided between the insulating layer 141A and the insulating layer 141 provided between the sub-pixels. The insulating layer 141 may be referred to as a partition wall, rib, or the like. For example, the insulating layer 141 and the insulating layer 141A may be referred to as a second insulating layer.

More specifically, the insulating layer 141 is provided between a functional layer 145 described later, the insulating layer 136 excluding the portion where the common electrode 140B and the insulating layer 137 are provided, the insulating layer 137 excluding the portion where the pixel electrode 143B is provided, the pixel electrode 143B, and a pixel electrode 149B provided in the groove 212 described later. In addition, the insulating layer 141 is provided between the functional layer 145 described later, the pixel electrode 149B provided in the groove 212 described later, the insulating layer 137, and the common electrode line 140V excluding the portion where the insulating layer 137 is provided. In addition, the insulating layer 141A is provided on the pixel electrode 143B and the opening 138B, on the insulating layer 137 excluding the portion where the pixel electrode 143B is provided, and between the groove 212B and the groove 212R.

A plurality of openings 144 is provided in the insulating layer 141. For example, as shown in FIG. 4, the opening 144 exposes sidewalls of the insulating layer 141 and a part of the surface of the conductive layer 139 (the common electrode 140B).

The functional layer 145 is provided to be in contact with the opening 144 and the conductive layer 139 (the common electrode 140) exposed by the opening 144. A configuration of the functional layer 145 can be selected as appropriate. The functional layer 145 is formed by combining a plurality of layers such as a carrier injection layer, a carrier transport layer, a light-emitting layer, a carrier blocking layer, and an exciton blocking layer. For example, in the organic EL display device 100 shown in FIG. 3 and FIG. 4, only the functional layer 145 (the light-emitting layers 145R, 145G, and 145B) among the plurality of layers is shown.

A region where the conductive layer 139 (the common electrode 140) and the functional layer 145 are in contact with each other serves as a light-emitting portion in each sub-pixel 109R, each sub-pixel 109G, and each sub-pixel 109B.

Although not shown, the functional layer 145 may include a first layer including a carrier (hole) injection and transport layer, a second layer which is the functional layer 145, and a third layer 146 including a carrier (electron) injection and transport layer. The functional layer 145 is formed to include different materials in the sub-pixel 109R, the sub-pixel 109G, and the sub-pixel 109B. As described in the section of “1-2. Configuration of Pixel 115,” in the organic EL display device 100, the sub-pixel 109R includes the light-emitting layer 145R, the sub-pixel 109G includes the light-emitting layer 145G, and the sub-pixel 109B includes the light-emitting layer 145B.

As shown in FIG. 2 and FIG. 3, the functional layer 145 is surrounded by the groove 212. Specifically, the light-emitting layer 145R is surrounded by the groove 212R, the light-emitting layer 145G is surrounded by the groove 212G, and the light-emitting layer 145B is surrounded by the groove 212B. The light-emitting layer 145R, the light-emitting layer 145G, and the light-emitting layer 145B are stepped (disconnected) by the groove 212R, the groove 212G, and the groove 212B, and are spaced apart from each other. That is, the groove 212R, the groove 212G, and the groove 212B have a function of suppressing mutual contact between the light-emitting layer 145R, the light-emitting layer 145G, and the light-emitting layer 145B, and protecting the light-emitting layer 145R, the light-emitting layer 145G, and the light-emitting layer 145B from mutual contact.

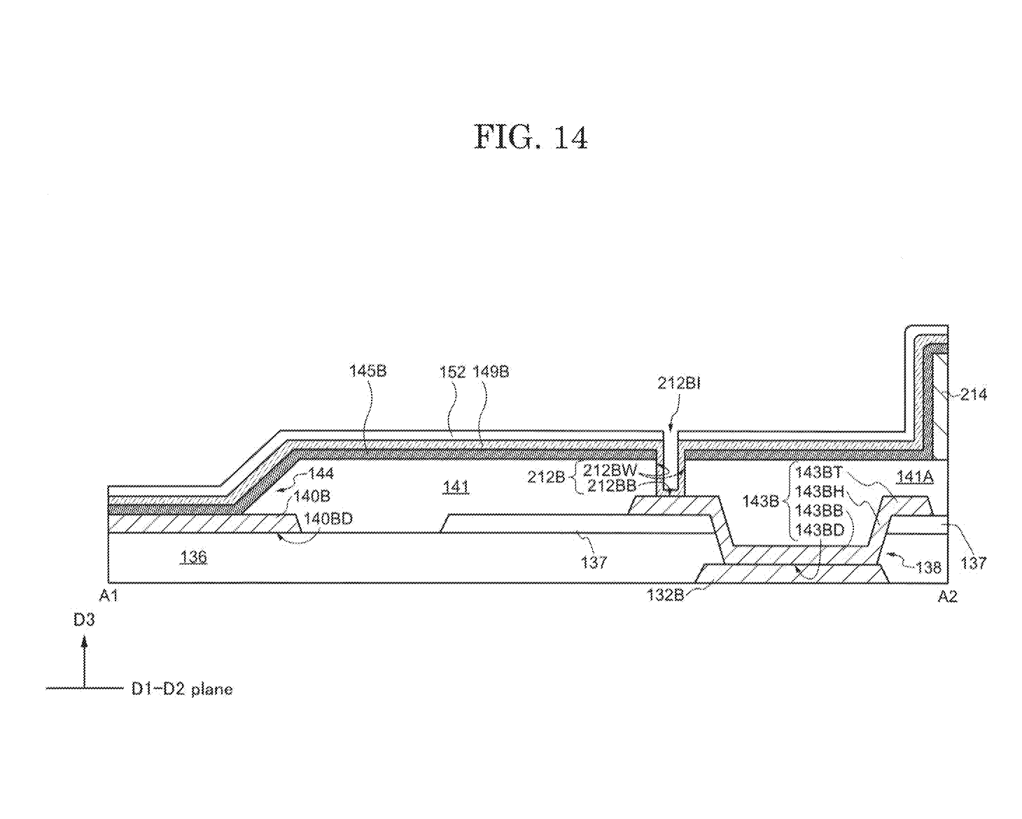

A pixel electrode 149 is provided on the functional layer 145 to cover the functional layer 145. In addition, the pixel electrode 149 is provided in the groove 212. The pixel electrode 149 is not provided on the insulating layer 141A and stepped (disconnected) by the groove 212 provided in each sub-pixel, and is separated for each pixel. On the other hand, since the pixel electrode 149 is provided in the groove 212, the lower end of the pixel electrode 149, positioned downward along an imaginary line parallel to the third direction D3, is exposed by the groove 212 and is in contact with the surface of the pixel electrode 143. The pixel electrode 149 includes the pixel electrode 149B, a pixel electrode 149G, and a pixel electrode 149R. Specifically, as shown in FIG. 4, in a portion where the pixel electrode 149B overlaps the pixel electrode 143B positioned downward along the imaginary line parallel to the third direction D3, the pixel electrode 149B provided in the groove 212B is connected to the electrode 132B via the pixel electrode 143B. Specifically, as shown in FIG. 5, in a portion where the pixel electrode 149B overlaps the common electrode 140B and the common electrode line 140V positioned downward along the imaginary line parallel to the third direction D3, the pixel electrode 149B provided in the groove 212B is in contact with the insulating layer 137 and apart from the common electrodes 140B and 140V. The pixel electrode 149G and the pixel electrode 149R are also formed similarly to the pixel electrode 149B. As described above, in a portion where the pixel electrode 149 overlaps the pixel electrode 143 positioned downward along the imaginary line parallel to the third direction D3, the pixel electrode 149 provided in each sub-pixel is stepped (disconnected) by the groove 212 and spaced apart from each other, but is connected to the pixel electrode 143 corresponding to each sub-pixel by being embedded in the groove 212. In addition, in a portion where the pixel electrode 149 overlaps the common electrode 140 positioned downward along the imaginary line parallel to the third direction D3, the pixel electrode 149 provided in each sub-pixel is stepped (disconnected) by the groove 212 and spaced apart from each other, and the pixel electrode 149 is in contact with the insulating layer 137 and apart from common electrode 140. That is, the pixel electrode 149 is connected to the pixel electrode 143, which should be electrically connected, by the groove 212, and is not connected to the common electrode 140, which should not be electrically connected (should be separated). In other words, the groove 212 includes a portion that makes the pixel electrode 149 conductive and a portion that does not make the pixel electrode 149 conductive depending on the position where the groove 212 is arranged. Although details will be described later, a groove 212BI (see FIG. 14) is formed by the pixel electrode 149B embedded in the groove 212B. The groove 212BI may be referred to as a second groove. The pixel electrode 149 may be referred to as an upper pixel electrode. The pixel electrode 143 may be referred to as a lower pixel electrode.

In the organic EL display device 100, a light-emitting element 150 is formed on the insulating layer 136. In addition, the light-emitting element 150 is formed in a region surrounded by the insulating layer 137. For example, the light-emitting element 150 is composed of the common electrode 140, the functional layer 145, and the pixel electrode 149. For example, when the transistor 133 of the sub-pixel 109R is driven, a desired current is supplied to the light-emitting element 150 (the light-emitting layer 145R), and the light-emitting element 150 of the sub-pixel 109R emits red light.

A sealing film 160 is provided on the light emitting element 150. The sealing film 160 includes an insulating layer 152, an inorganic insulating layer 153, an organic insulating layer 154, and an inorganic insulating layer 156. For example, the insulating layer 152 may be referred to as a third insulating layer, the inorganic insulating layer 153 may be referred to as a fifth inorganic insulating layer, and the inorganic insulating layer 156 may be referred to as a sixth inorganic insulating layer.

The insulating layer 152 is provided on the pixel electrode 149. Similar to the functional layer 145, the insulating layer 152 is stepped for each pixel by the groove 212 and spaced apart from each other for each pixel. The insulating layer 152 is not provided in the groove 212 and is spaced apart from the groove 212.

The inorganic insulating layer 153 is provided on the insulating layer 152 and the pixel electrode 149. The inorganic insulating layer 153 provided on the pixel electrode 149 is embedded in the groove 212BI. The inorganic insulating layer 153 includes an overhang part 153E provided spaced apart from the insulating layers 141 and 141A. The overhang part 153E includes an overhang part 153BE and an overhang part 153RE. In the cross-sectional views shown in FIG. 3 to FIG. 5, the overhang part 153E extends in the first direction D1 and the second direction D2 from the groove 212, and in a plan view, the overhang part 153E overlaps the pixel electrode 149 exposed to the insulating layer 141A and a portion of the insulating layer 141A. In addition, the inorganic insulating layer 153 is spaced apart from each other for each pixel, similar to the insulating layer 152. For example, the inorganic insulating layer 153 covers the functional layer 145, the pixel electrode 149, and the insulating layer 152 corresponding to the sub-pixels, and suppresses the functional layer 145, the pixel electrode 149, and the insulating layer 152 from being unnecessarily exposed to a gas, a solution, or the like when processing the respective layers and disappearing. In addition, positions of the sub-pixels are clarified by the positions at which the overhang parts 153BE and 153RE of the inorganic insulating layer 153 are arranged. In addition, although not shown, the inorganic insulating layer 153 included in the sub-pixel 109G has an overhang part for the sub-pixel 109G similar to the overhang part 153BE and the overhang part 153RE.

In addition, as shown in FIG. 5, a space 162 is provided (formed) between the overhang part 153BE of the sub-pixel 109B, the overhang part 153RE of the sub-pixel 109R, and the insulating layer 141A between the groove 212B of the sub-pixel 109B and the groove 212B of the sub-pixel 109R.

The organic insulating layer 154 is provided to cover at least the display section 102. Specifically, the organic insulating layer 154 is provided on (a surface of) the inorganic insulating layer 153 and in the space 162.

The inorganic insulating layer 156 is provided to cover at least the display section 102. Specifically, the inorganic insulating layer 156 is provided on (a surface of) the organic insulating layer 154. A cover film 158 is provided on the inorganic insulating layer 156.

As shown in FIG. 4, a width W5 of the bottom portion 143BB (the lower surface 143BD) of the pixel electrode 143B is the same as a width of a bottom portion of the opening 138. As shown in FIG. 4 or FIG. 5, the width W5 is wider than a width W1 of a bottom portion 212BB of the groove 212B and a width W4 of a bottom portion 212RB of the groove 212R. The width W1 may be the same as the width W4. A length L1 extending along the second direction D2 of the overhang part 153BE may be the same as a length L2 extending along the second direction D2 of the overhang part 153RE. A width W3 of the insulating layer 141A is wider than a width W2 between the overhang part 153BE and the overhang part 153RE. That is, the overhang part 153BE and the overhang part 153RE overlap a portion of the insulating layer 141A. In addition, the bottom portion 143BB (the lower surface 143BD, the bottom portion of the opening 138) of the pixel electrode 143B is provided below the bottom portion 212BB of the groove 212B and the bottom portion 212RB of the groove 212R along the imaginary line parallel to the third direction D3.

For example, a substrate such as a silicon wafer, a sapphire substrate, or the like can be used to form an organic EL device, using a substrate with a suitable size for an IC manufacturing process, such as a driver IC. In the IC manufacturing process, a plug that fills a deep opening and a fine groove can easily be formed along the third direction D3. Therefore, for example, even if the pixel electrode is provided above the bottom portion of the fine groove along the imaginary line parallel to the third direction D3, the conductive layer is provided below the bottom portion of the fine groove along the imaginary line parallel to the third direction D3, and the conductive layer is provided at a position deeper from the pixel electrode along the imaginary line parallel to the third direction, the pixel can be easily miniaturized, a connecting position between the pixel electrode and the plug is above a position of the bottom portion of the fine groove along the imaginary line parallel to the third direction D3, and the pixel electrode can be connected to the pixel electrode and the conductive layer provided below the fine groove along the imaginary line parallel to the third direction D3 via the plug formed in the deep opening.

On the other hand, for example, since a large glass substrate is used for the substrate 101 of the organic EL display device 100, it is difficult to form the plug that fills the deep opening and the fine groove along the imaginary line parallel to the third direction D3, as formed in the IC manufacturing processes. Therefore, in the organic EL display device 100 according to an embodiment of the present invention, the pixel electrode 143B is provided below the bottom portion 212BB of the groove 212B along the imaginary line parallel to the third direction D3, and the pixel electrode 143B is electrically connected to the electrode 132B. In addition, the pixel electrode 143B is provided spaced apart from the common electrode 140B. Although details will be described later, the groove 212 is formed by a sidewall formed using an inorganic insulating layer 206. As a result, for example, since the width W5 of the bottom portion 143BB (the lower surface 143BD, the opening 138) for connecting the flat portion 143BT of the pixel electrode 143B and the electrode 132B is narrower than a width of the deep opening, and the groove 212B does not depend on the resolution of photolithography, the pixel 115 (the sub-pixels 109R, 109G, and 109B) in the organic EL display device 100 can be miniaturized. In addition, the width W5 and the like can be adjusted depending on the fine groove 212.

### 1-4. Material of Each Member of Organic EL Display Device 100

A glass substrate, a quartz substrate, or the like is used as the substrate 101.

For example, the semiconductor layer 122 includes a Group 14 element such as silicon (Si) or germanium (Ge), or an oxide that exhibits semiconductor properties. For example, the semiconductor layer 122 including the Group 14 element may include crystalline silicon. The crystalline silicon may be low-temperature polysilicon (LTPS) or single-crystal silicon. In addition, in the case where the semiconductor layer 122 is crystalline silicon, impurities according to a polarity of the transistor are implanted into the source section 124A and the drain section 124B. For example, a metal oxide (oxide semiconductor) having semiconductor characteristics may be included as an oxide exhibiting semiconductor properties.

For example, a general inorganic insulating layer such as silicon oxide (SiO₂), silicon oxide (SiON), and the like can be used as the gate insulating layer 125, the insulating layer 128, the insulating layer 137, the insulating layer 152, the inorganic insulating layer 153, and the inorganic insulating layer 156.

An organic compound material selected from acrylic, polyimide, and the like, which has excellent film surface flatness, can be used as the insulating layer 131, the insulating layer 136, and the organic insulating layer 154. The insulating layer 131, the insulating layer 136, the insulating layer 141, and the organic insulating layer 154 cover irregularities caused by the transistor and other semiconductor elements, and the surfaces of the insulating layer 131, the insulating layer 136, and the organic insulating layer 154 become flat surfaces.

The sealing film 160 suppresses impurities (moisture, oxygen, and the like) from entering the light-emitting element 150, the transistor, or the like from the outside. Although not shown, for example, the insulating layer 152, the inorganic insulating layer 153, and the inorganic insulating layer 156 are in direct contact with each other around the organic EL display device 100. As a result, the organic EL display device 100 can suppress impurities from entering from the outside.

### 2. Second Embodiment

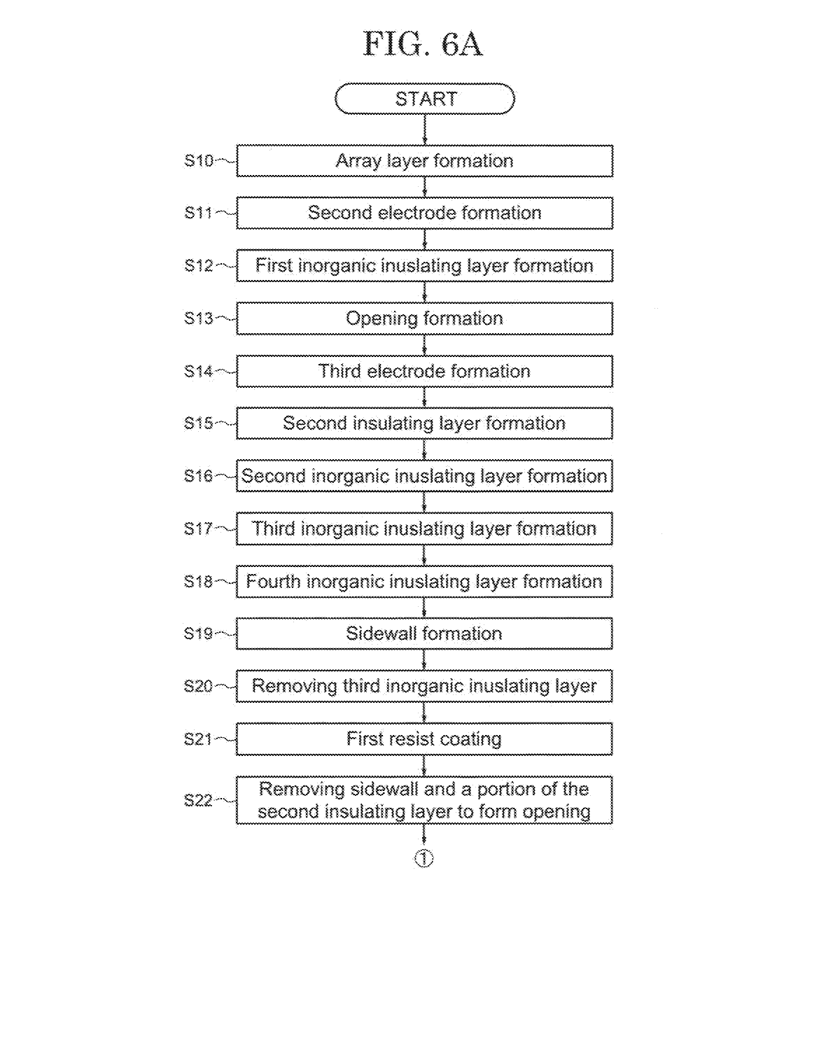

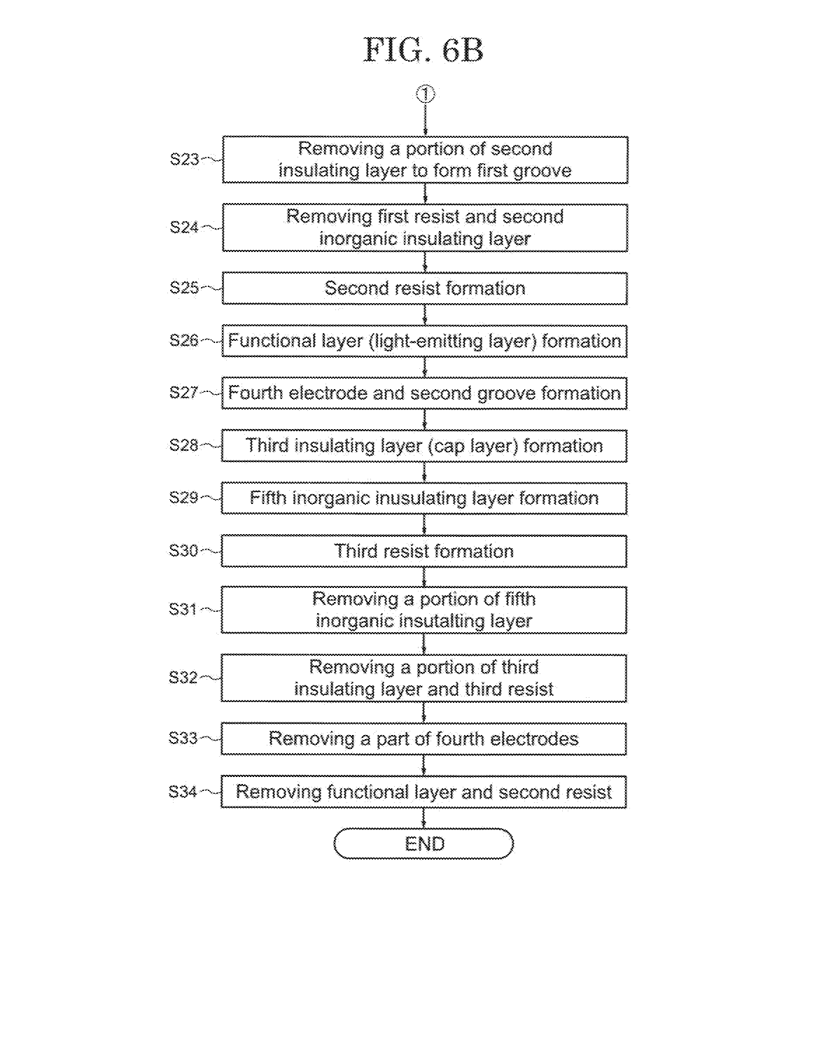

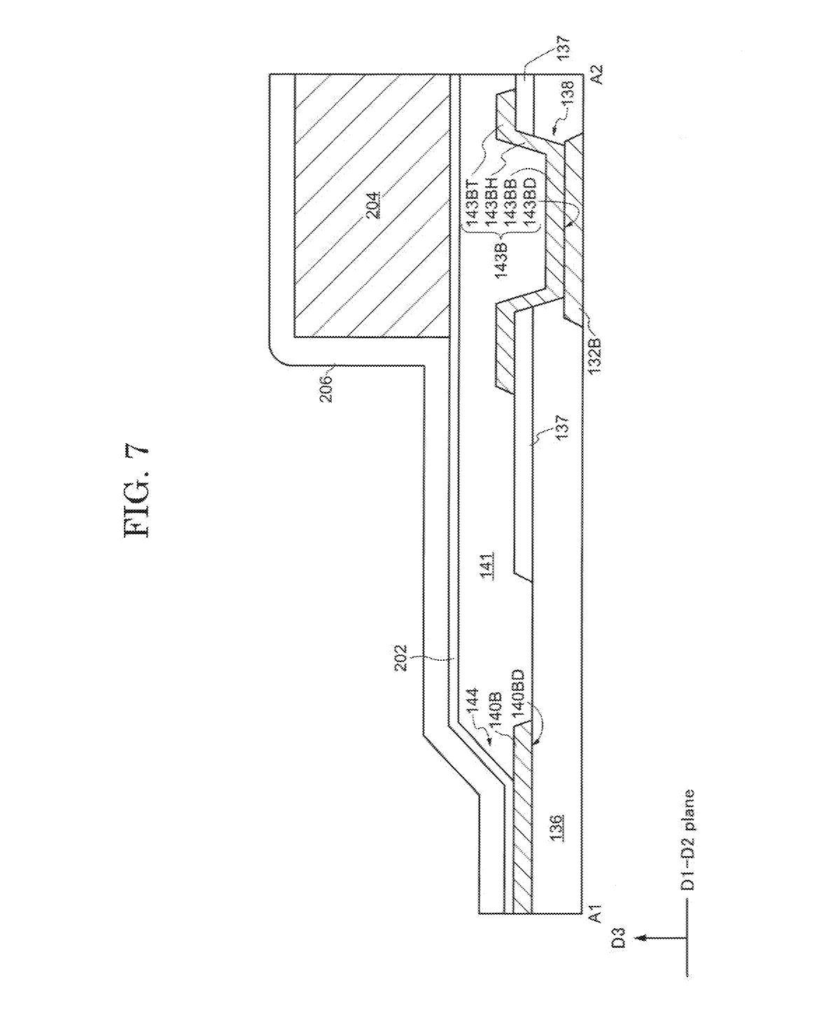

An overview of a method for manufacturing the organic EL display device 100 will be described with reference to FIG. 3 to FIG. 19. FIG. 6A and FIG. 6B are sequence diagrams showing the method for manufacturing the organic EL display device 100. FIG. 7 to FIG. 19 are cross-sectional views showing a structure of a cross-section taken along the line A1-A2 of the pixel 115 shown in FIG. 2. Configurations that are the same as or similar to those in FIG. 1 to FIG. 4 will be described as necessary.

As shown in FIG. 6A, the array layer 170 is formed (step 10 (S10) in FIG. 6A). Specifically, as shown in FIG. 3, when the manufacturing of the organic EL display device 100 is started, the underlayer 121 is formed on the first surface 101A of the substrate 101. The semiconductor layer 122 is formed on the underlayer 121. Impurities are implanted into the semiconductor layer 122 to form the source section 124A and the drain section 124B. The gate insulating layer 125 is formed on the semiconductor layer 122 and on the underlayer 121 where the semiconductor layer 122 is not formed. The conductive layer 126 is formed on the gate insulating layer 125. The conductive layer 126 includes the gate electrode 127. The insulating layer 128 is formed on the conductive layer 126 and on the gate insulating layer 125 where the conductive layer 126 is not formed. The capacitance line 130 is formed on the insulating layer 128. The insulating layer 131 is formed on the capacitance line 130 and on the insulating layer 128 where the capacitance line 130 is not formed. The opening 135 is opened. Each of the openings opens the gate insulating layer 125, the insulating layer 128, and the insulating layer 131 to expose a wiring, a semiconductor layer, or an electrode corresponding to each of the openings. For example, the opening 135 exposes the semiconductor layer 122A (for example, the source section 124A). Other openings also expose corresponding wirings, semiconductor layers, or electrodes. The conductive layer 132 is formed on the insulating layer 131. The conductive layer 132 (first electrode) includes the electrode 132A. For example, the electrode 132A is electrically connected to the semiconductor layer 122 through the opening 135. As shown in FIG. 3, FIG. 4, and FIG. 7, the insulating layers 136 and 137 are formed on the conductive layer 132 and on the insulating layer 131 where the conductive layer 132 is not formed. As described above, the array layer 170 is formed.

As shown in FIG. 3, FIG. 4, and FIG. 7, the common electrode 140 (e.g., the common electrode 140B) is formed on the insulating layer 136 (step 11 (S11) in FIG. 6A). For example, as described above, the common electrode 140 may be referred to as the second electrode.

As shown in FIG. 3, FIG. 4, and FIG. 7, the insulating layer 137 is formed on the insulating layer 136 where the common electrode 140 is not formed (step 12 (S12) in FIG. 6A). As described in the section of “1-3. Cross Section of Organic EL Display Device 100,” the insulating layer 137 is provided in the same layer as the common electrode 140 and is spaced apart from the common electrode 140. For example, as described above, the insulating layer 137 may be referred to as the first inorganic insulating layer.

As shown in FIG. 3, FIG. 4, and FIG. 7, the opening 138 (for example, the opening 138B) is opened (step 13 (S13) in FIG. 6A). Each opening opens the insulating layer 136 and the insulating layer 137, and exposes the wiring or electrode corresponding to each opening. For example, the opening 138 exposes the electrode 132A. Other openings also expose the corresponding wiring or electrodes.

The pixel electrode 143 (for example, the pixel electrode 143B) is formed on the top (part of the upper surface) and sidewalls of the insulating layer 137, the sidewalls of the insulating layer 136, and on the electrode 132A exposed at the opening 138 (step 14 (S14) in FIG. 6A). For example, as described above, the pixel electrode 143 may be referred to as a third electrode.

The insulating layer 141 is formed on the insulating layer 136 excluding the portion where the common electrode 140 and the insulating layer 137 are formed, on the common electrode 140, on the pixel electrode 143 (the opening 138), and on the insulating layer 137 excluding the portion where the pixel electrode 143 is formed (step 15 (S15) in FIG. 6A). For example, as described above, the insulating layer 141 may be referred to as the second insulating layer. In addition, For example, the insulating layer 141 is an inorganic insulating layer.

The opening 144 is formed at a position where the functional layer 145 of the common electrode 140 is arranged, and an insulating layer 202 is formed on the insulating layer 141 exposed by the opening 144 (upper surface and sidewalls (side surfaces)), and on the common electrode 140 where the insulating layer 141 is not formed (step 16 (S16) in FIG. 6A). For example, the insulating layer 202 includes silicon nitride (SiN). For example, the insulating layer 202 may be referred to as a second inorganic insulating layer.

An insulating layer 204 is formed on a part of the conductive layer 143 and the insulating layer 202 that overlaps the insulating layer 141 (step 17 (S17) in FIG. 6A). For example, the insulating layer 204 includes silicon oxide (SiO₂). For example, the insulating layer 204 may be referred to as a third inorganic insulating layer.

The inorganic insulating layer 206 is formed on the insulating layer 202 where the insulating layer 204 is not formed and on an upper surface (surface) and side surfaces (sidewalls) of the insulating layer 204 (step 17 (S17) in FIG. 5A). For example, the inorganic insulating layer 206 includes silicon nitride (SiN). For example, the inorganic insulating layer 206 may be referred to as a fourth inorganic insulating layer.

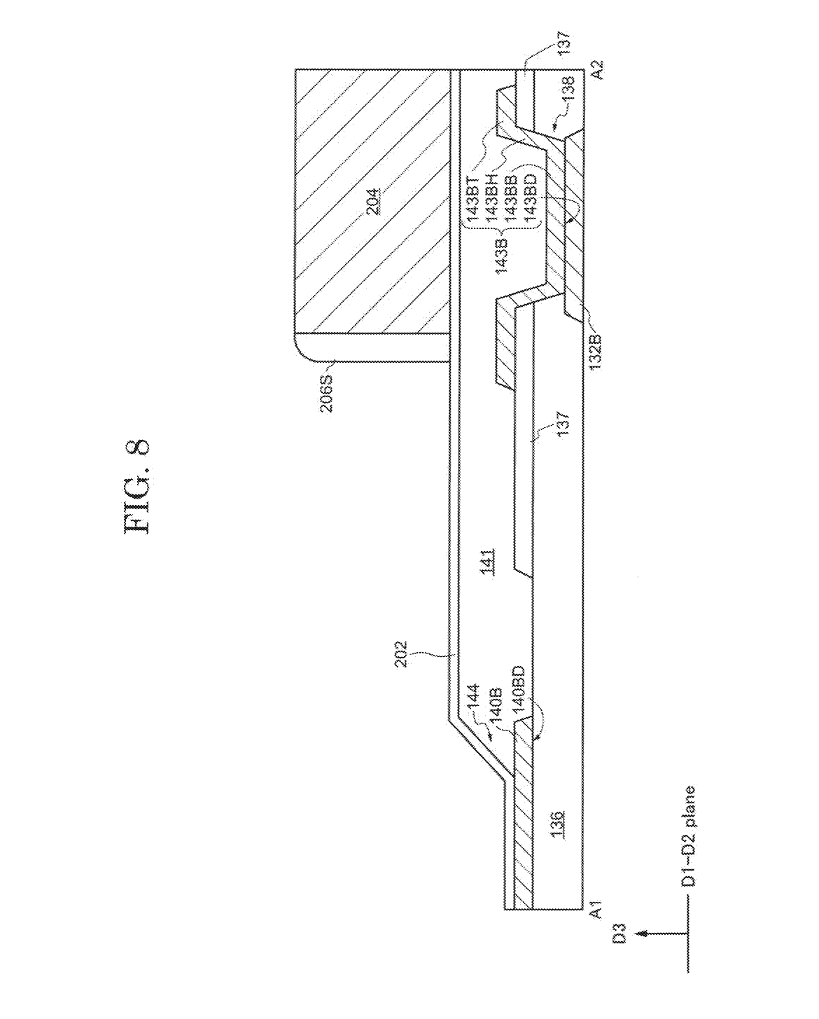

As shown in FIG. 8, the inorganic insulating layer 206 on the insulating layer 202 and the inorganic insulating layer 206 on the upper surface (surface) of the insulating layer 204 are removed by anisotropic dry etching, a part of the inorganic insulating layer 206 formed on the side surfaces (sidewalls) of the insulating layer 204 remains, and a sidewall 206S is formed (step 19 (S19) in FIG. 6A).

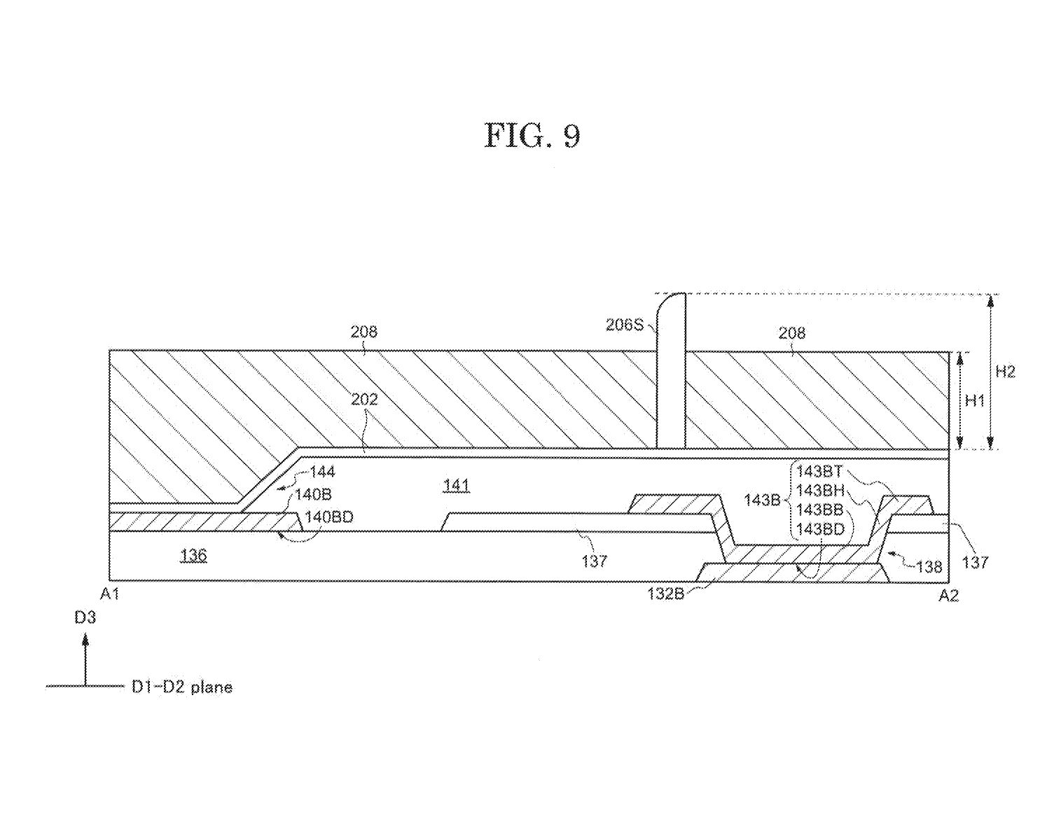

As shown in FIG. 9, the insulating layer 204 is removed (step 20 (S20) in FIG. 6A), and a first resist 208 is applied on the insulating layer 202 where the sidewall 206S is not formed (step 21 (S21) in FIG. 6A). With respect to the surface of the insulating layer 202, a height H1 is adjusted so that a height H2 of the top of the sidewall 206S is higher than the height (thickness) H1 of a surface of the first resist 208. The first resist 208 is a resist having good planarity.

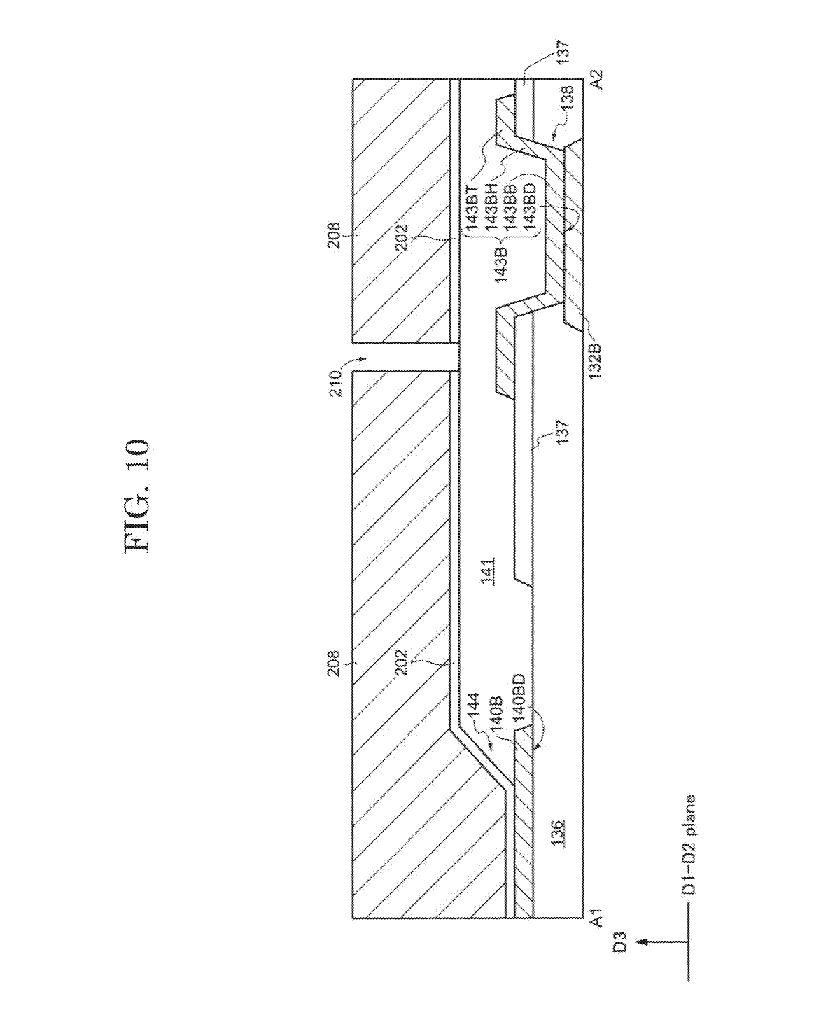

As shown in FIG. 10, the sidewall 206S is removed, the insulating layer 202 exposed by removing the sidewall 206S is removed using the first resist 208 as a mask, and an opening 210 is formed (step 22 (S22) in FIG. 6A).

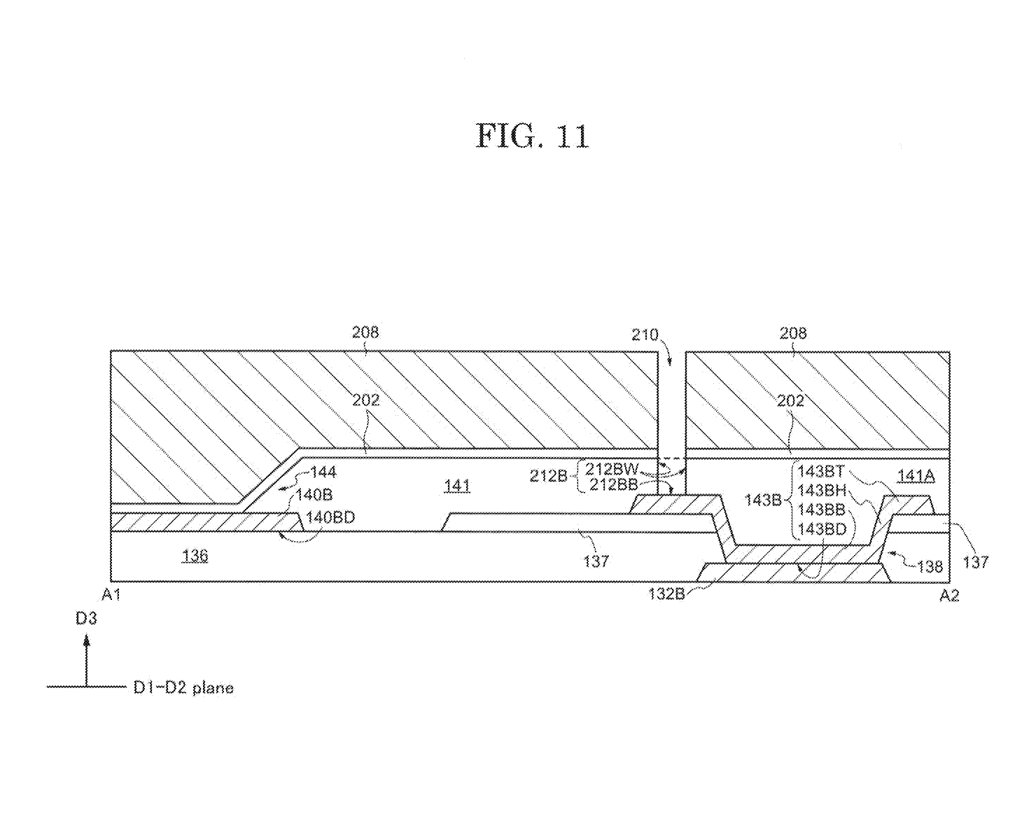

As shown in FIG. 11, the insulating layer 141 exposed by removing the insulating layer 202 is removed using the first resist 208 and the insulating layer 202 as the mask, and the groove 212B that exposes a part of the conductive layer 143 is formed (step 23 (S23) in FIG. 6B). For example, the width W1 of the groove 212B and the width W4 of the groove 212R may be 180 nm or more and 220 nm or less. For example, the width W1 of the groove 212B and the width W2 of the groove 212R are 200 nm. A width of the groove 212G is the same as the width W1 and the width W2. The width W1 of the groove 212B and the width W2 of the groove 212R are determined by a thickness of the fourth inorganic insulating layer 206, and do not depend on the resolution of photolithography.

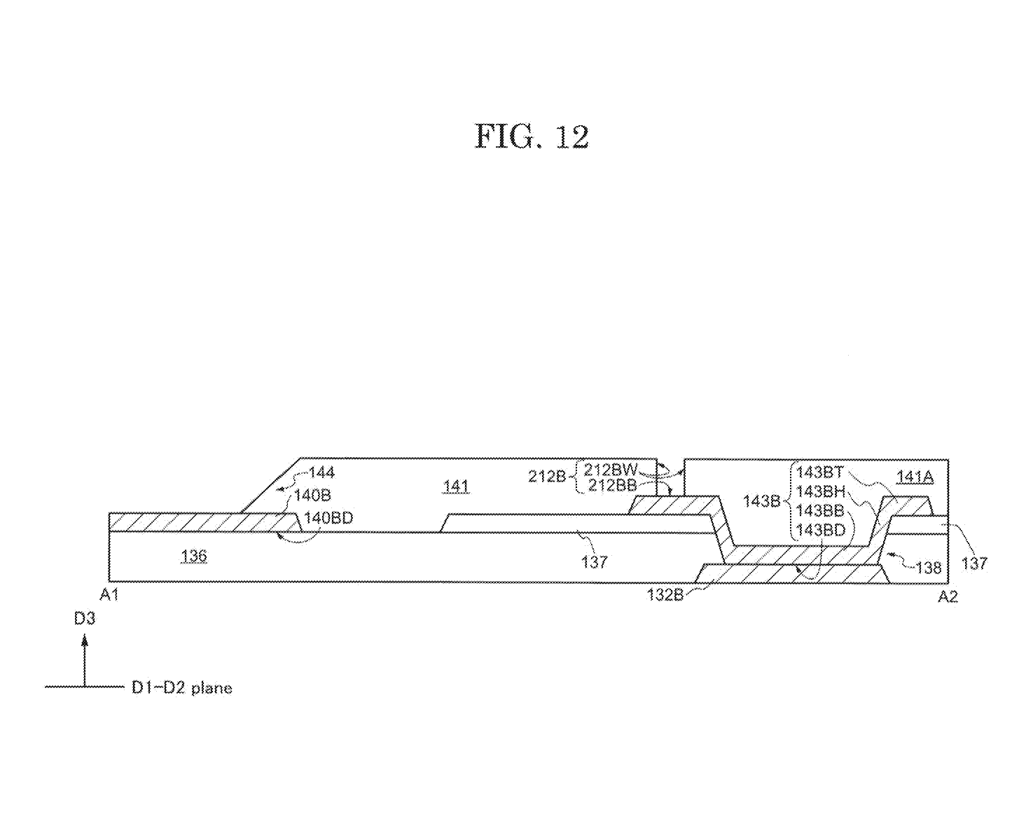

As shown in FIG. 12, the first resist 208 and the insulating layer 202 are removed (step 24 (S24) in FIG. 6B).

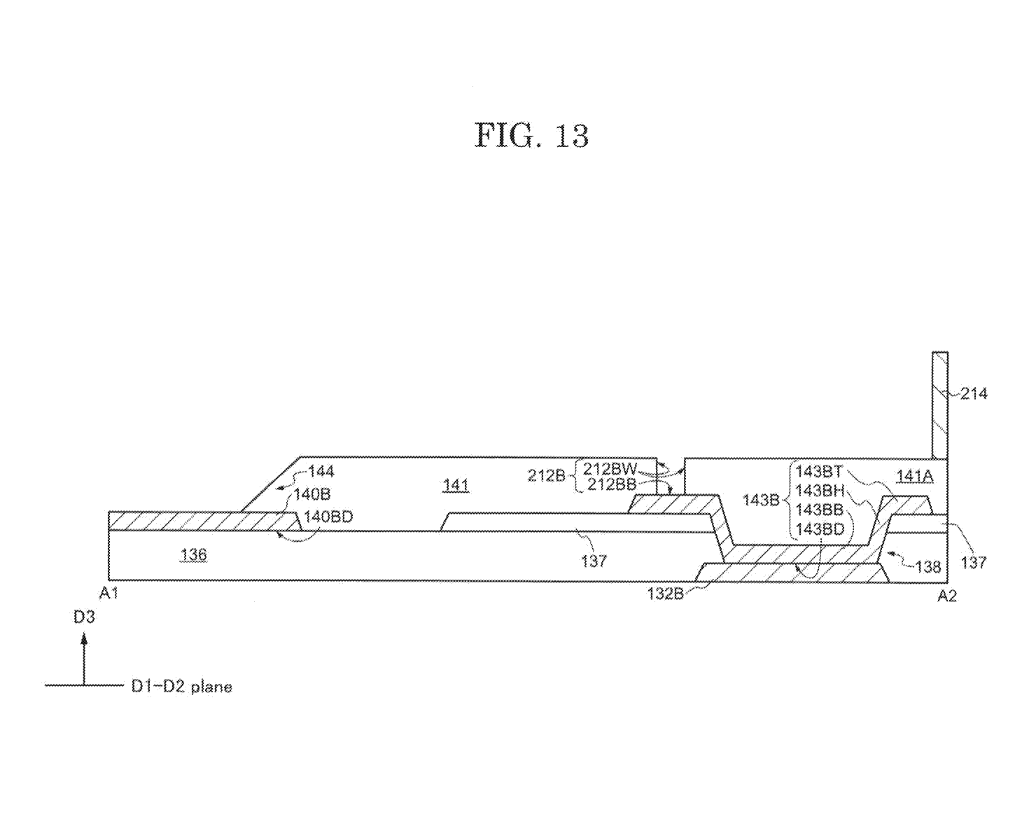

After the groove 212 (in this case, the groove 212B) is formed, the sub-pixel 109R, the sub-pixel 109G, and the sub-pixel 109B are formed in a similar step, respectively. In this case, the step in which the sub-pixel 109B is formed will be described. As shown in FIG. 13, a second resist 214 is applied on a portion of the insulating layer 141 to mask the sub-pixels 109G and 109B other than the sub-pixel 109R (step 25 (S25) in FIG. 6B). For example, as described above, the groove 212 may be referred to as the first groove.

As shown in FIG. 14, the functional layer 145 (in this case, the light-emitting layer 145B for emitting blue light) is formed (step 26 (S26) in FIG. 6B). Since the light-emitting layer 145B is formed by a vapor deposition method, it is not formed at least on the bottom portion 212BB of the groove 212B, but is stepped with the groove 212B as a boundary. That is, the light-emitting layer 145B is formed on the top (surface) of the common electrode 140 (in this case, the common electrode 140B) exposed by the opening 144, the sidewalls (side surfaces) and a portion of the surface of the insulating layer 141 on which the second resist 214 is not applied, and the sidewalls and the upper surface of the second resist 214, and is not formed in the groove 212B, but is stepped with the groove 212B as a boundary. Therefore, the light-emitting layer 145B is connected to the surface of the common electrode 140 exposed by the opening 144 and is spaced apart from and not connected to the conductive layer 143. As a result, for example, as shown in FIG. 2 and FIG. 3, the groove 212B surrounds the light-emitting layer 145B. As shown in FIG. 2 and FIG. 3, similar to the groove 212B, the groove 212R surrounds the light-emitting layer 145R, and the groove 212G surrounds the light-emitting layer 145G.

As shown in FIG. 14, the pixel electrode 149 (in this case, the pixel electrode 149B) is formed on the light-emitting layer 145B using a sputtering device, and the groove 212BI is formed (step 27 (S27) in FIG. 6B). Specifically, the pixel electrode 149B is formed using the sputtering device, so that the pixel electrode 149B is embedded in an upper surface and side surfaces of the light-emitting layer 145B and a sidewall 212BW and the bottom portion 212BB of the groove 212B. As a result, the pixel electrode 149B is connected to a portion of the conductive layer 143B exposed by the groove 212B. A groove of the pixel electrode 149B formed inside the groove 212B reflecting a shape of the groove 212B is the groove 212BI. For example, as described above, the pixel electrode 149 may be referred to as a fourth electrode. In addition, as described above, the groove 212BI (although not shown, a groove 212RI and a groove 212GI) may be referred to as the second groove.

As shown in FIG. 14, the insulating layer 152 is formed (step 28 (S28) in FIG. 6B). Since the insulating layer 152 is formed by a vapor deposition method similar to the light-emitting layer 145B, it is not formed at least at the bottom portion of the groove 212BI, but is stepped with the groove 212BI as a boundary. That is, the insulating layer 152 is formed on the pixel electrode 149 other than the groove 212BI and is not formed in the groove 212BI, but is stepped with the groove 212BI as a boundary. Therefore, the insulating layer 152 is formed to be spaced apart from the conductive layer 143. The insulating layer 152 is a so-called cap layer for protecting the pixel electrode 149 and the light-emitting layer 145B.

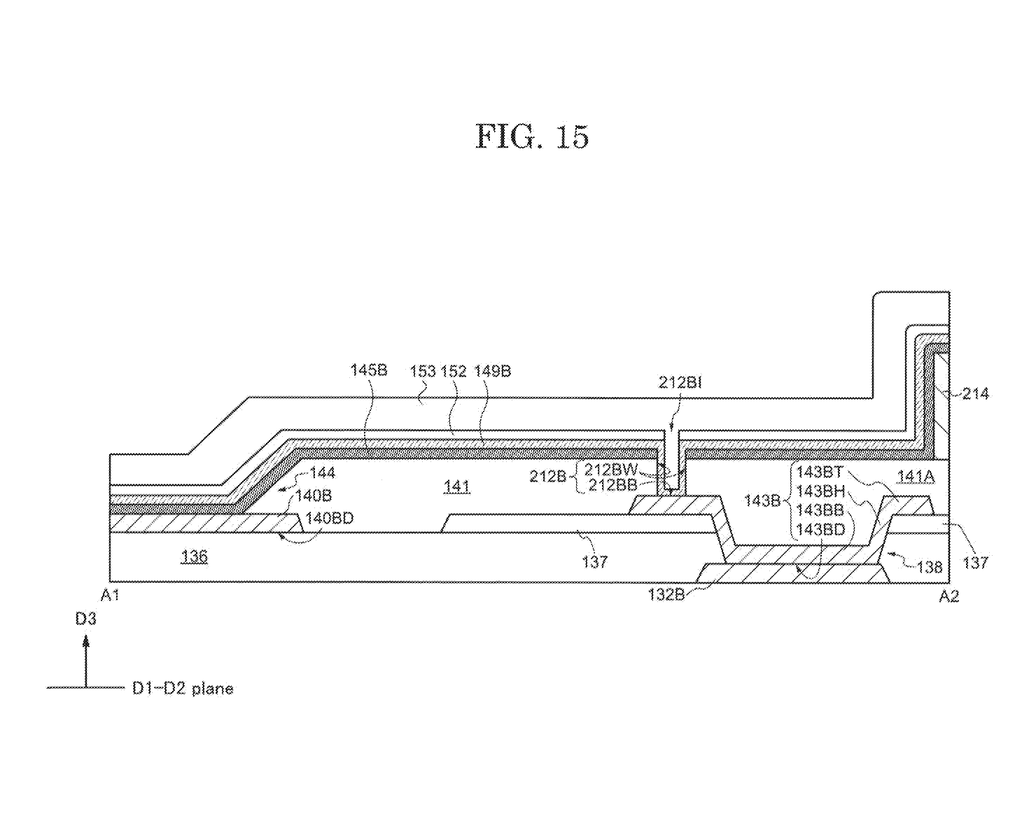

As shown in FIG. 15, the inorganic insulating layer 153 is formed in (inside of) the groove 212BI and on (the surface of) the insulating layer 152 (step 29 (S29) in FIG. 6B). For example, as described above, the inorganic insulating layer 153 may be referred to as the fifth inorganic insulating layer.

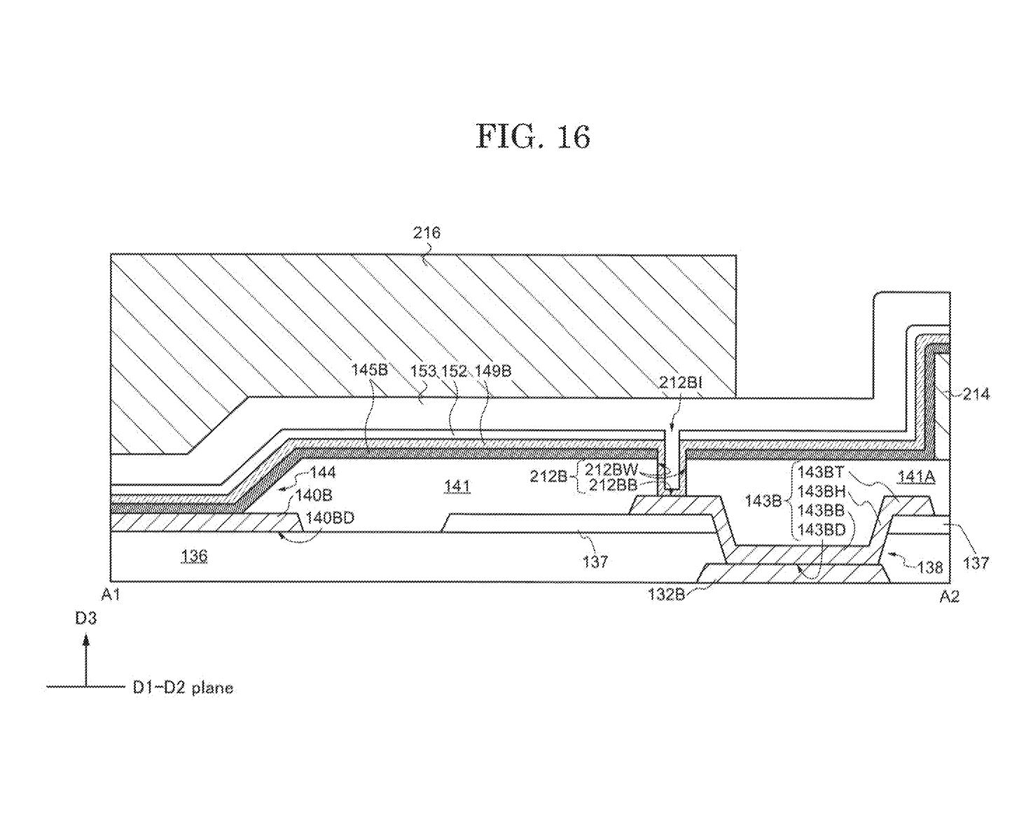

As shown in FIG. 16, a third resist 216 is formed on (the surface of) a portion of the insulating layer 152 (step 30 (S30) in FIG. 6B).

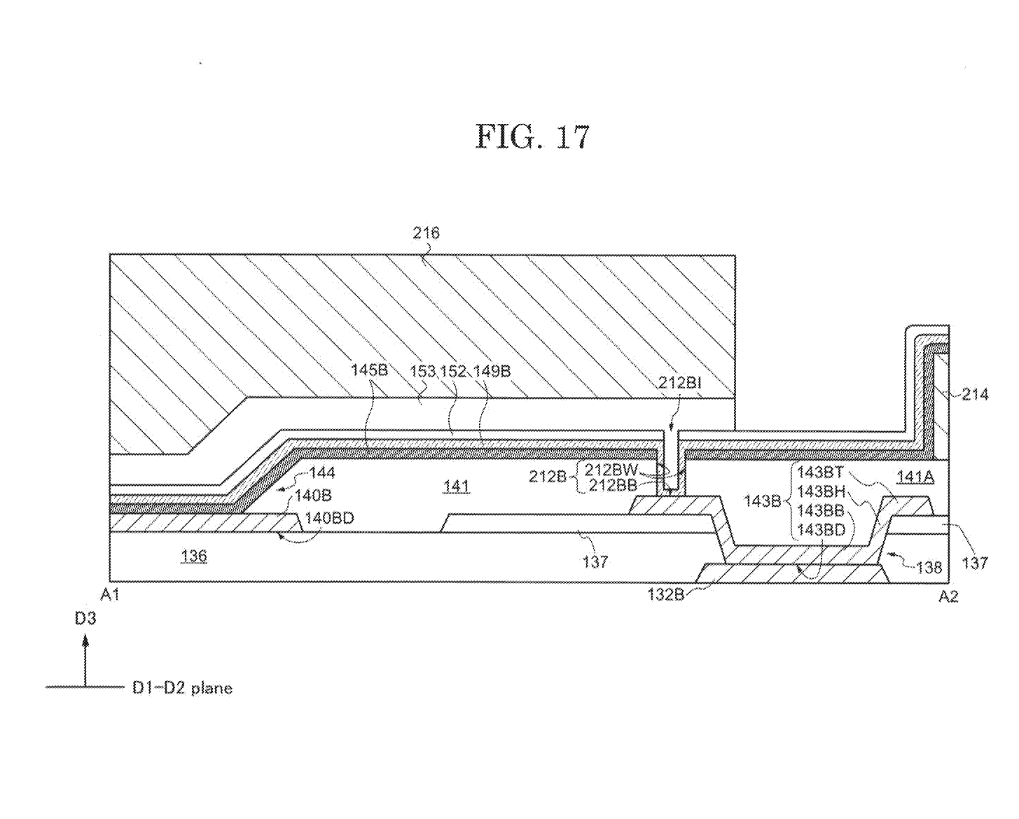

As shown in FIG. 17, the inorganic insulating layer 153, excluding the inorganic insulating layer 153 overlapping the third resist 216, is removed by, for example, anisotropic dry etching (step 31 (S31) in FIG. 6B). In S31, a portion of the inorganic insulating layer 153, that is, the inorganic insulating layer not overlapping the third resist 216 is removed.

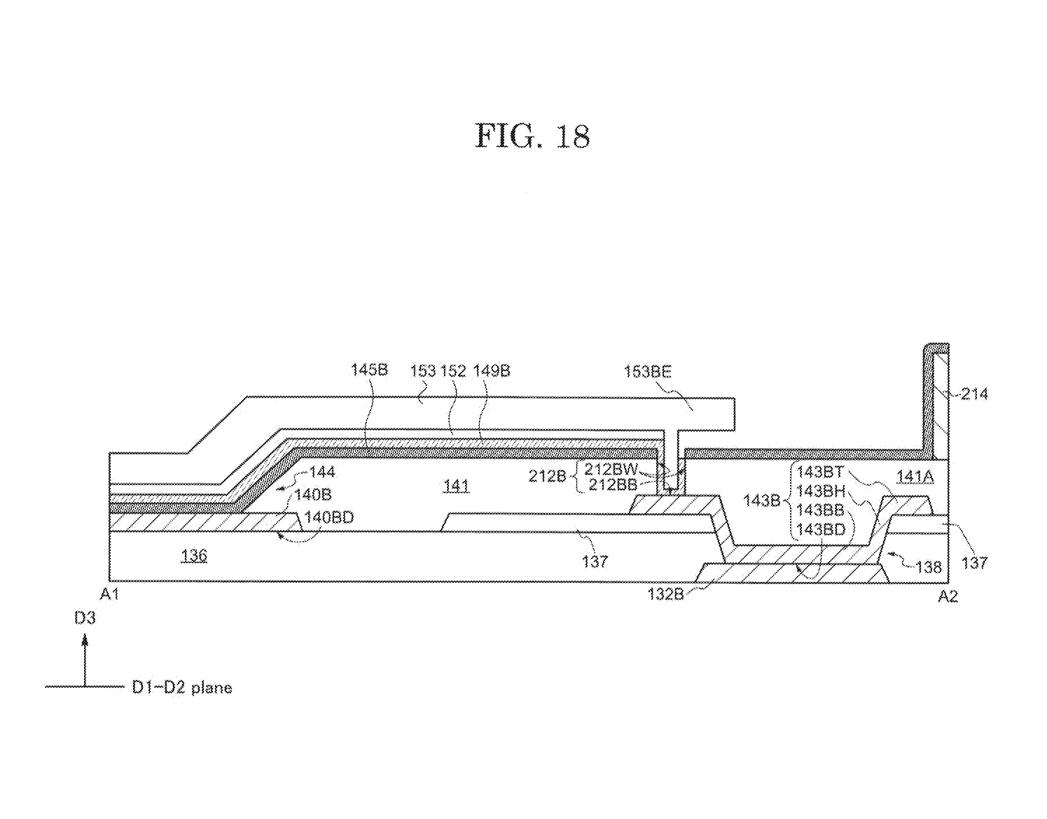

For example, as shown in FIG. 18, in the case where the insulating layer 152 extending along the first direction D1 and the second direction D2 is an organic insulating layer compared with the insulating layer 152 formed in the groove 212BI, the insulating layer 152 is removed by, for example, an oxygen-plasma treatment (step 32 (S32) in FIG. 6B). In this case, the third resist 216 is also removed simultaneously by the oxygen plasma. In S32, the third resist 216 and a portion of the insulating layer 152, that is, the insulating layer 152 that does not overlap the third resist 216 and the insulating layer 152 below the overhang part 153BE of the inorganic insulating layer 153 along the imaginary line parallel to the third direction D3 are removed. In addition, the removal of the insulating layer 152 and the removal of the third resist 216 in S32 are not limited to oxygen plasma. Oxygen plasma is an example, and any treatment other than oxygen plasma may be used as long as it can remove the insulating layer 152 and the third resist 216.

As shown in FIG. 18, the pixel electrode 149 extending along the first direction D1 and the second direction D2 from the insulating layer 152 formed in the groove 212BI, and the pixel electrode 149, excluding the pixel electrode 149 between the insulating layer 141A and the groove 212BI, is removed by, for example, dry etching (step 33 (S33) in FIG. 6B). In S33, a portion of the pixel electrode 149, that is, the pixel electrode 149 that does not overlap the inorganic insulating layer 153 and the common electrode 149 between the overhang part 153BE and the groove 212B of the inorganic insulating layer 153 along the imaginary line parallel to the third direction D3 are removed.

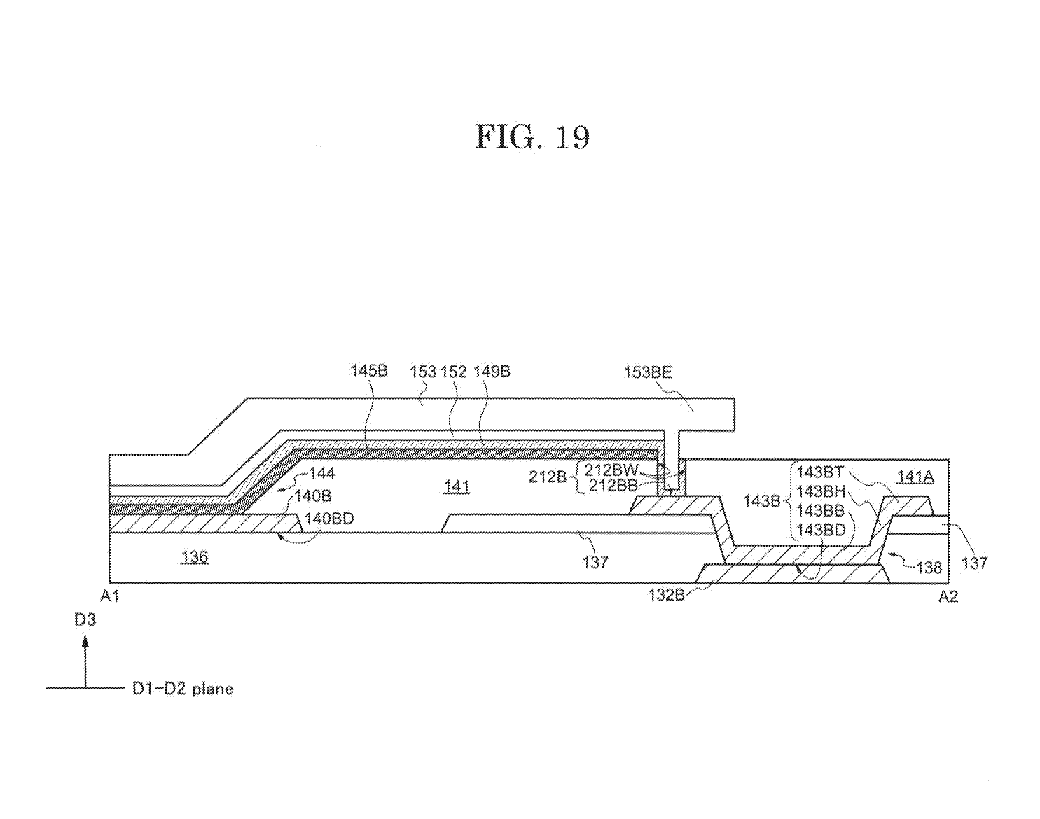

As shown in FIG. 19, the light-emitting layer 145B extending along the first direction D1 and the second direction D2 from the insulating layer 152 formed in the groove 212BI, and the second resist 214 are removed by, for example, the oxygen plasma treatment (step 34 (S34) in FIG. 6B). As a result, the overhang part 153BE is formed.

The structures up to the inorganic insulating layer 153 in the sub-pixel 109B are formed through S25 to S34. Similar to the sub-pixel 109B, by repeating S25 to S34, structures up to the inorganic insulating layer 153 in the sub-pixel 109G and the sub-pixel 109R are formed.

As shown in FIG. 3 to FIG. 5, after S34, the organic insulating layer 154 is formed in the space 162 provided below the overhang part 153BE along the imaginary line parallel to the third direction D3 between the overhang part 153BE and the insulating layer 141A and on the inorganic insulating layer 153. After the organic insulating layer 154 is formed, the inorganic insulating layer 156 and the cover film 158 are formed. As described above, the organic EL display device 100 is formed.

The organic EL display device 100 is formed by the manufacturing method described above. The method for manufacturing the organic EL display device 100 includes forming the pixel electrode 143 to be provided below the bottom portion 212BB of the groove 212B along the imaginary line parallel to the third direction D3, and forming the conductive layer 132 at a shallow position below the common electrode 140 along the imaginary line parallel to the third direction D3. The method for manufacturing the organic EL display 100 includes forming the groove 212 by the sidewall 206S formed using the inorganic insulating layer 206. As a result, in the method for manufacturing the organic EL display device 100, the width W5 of the bottom portion 143BB (the lower surface 140BD) (the opening 138) for connecting the flat portion 143BT of the pixel electrode 143 and the electrode 132B can be formed to be narrower than the width of the opening formed deeper, the width W1 and the width W4 of the groove 212 that do not depend on the resolution of photolithography can be formed, and the pixel 115 (the sub-pixels 109R, 109G, and 109B) can be miniaturized.

### 3. Third Embodiment

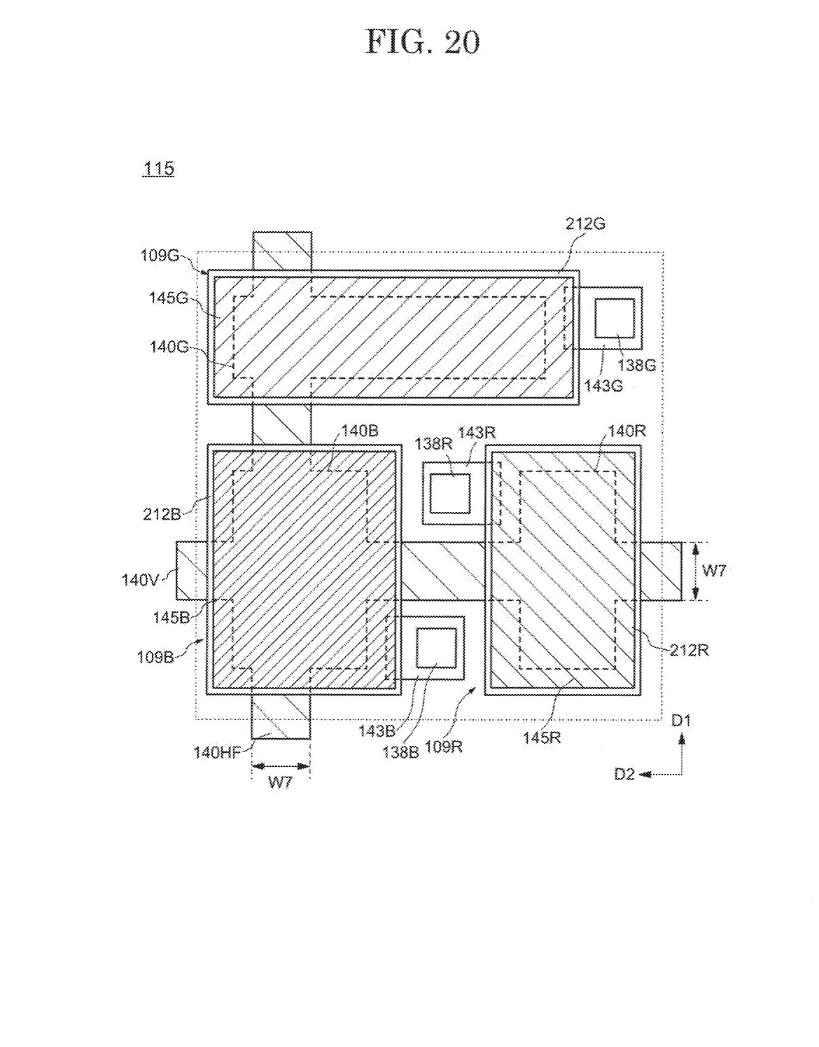

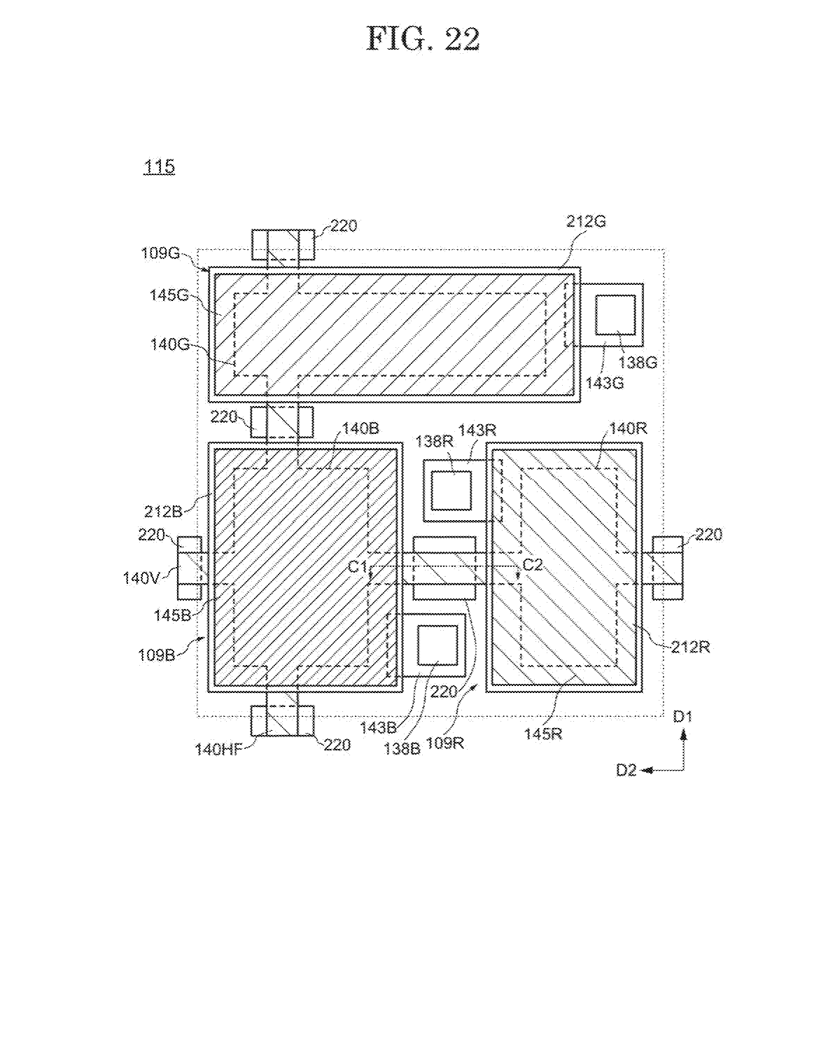

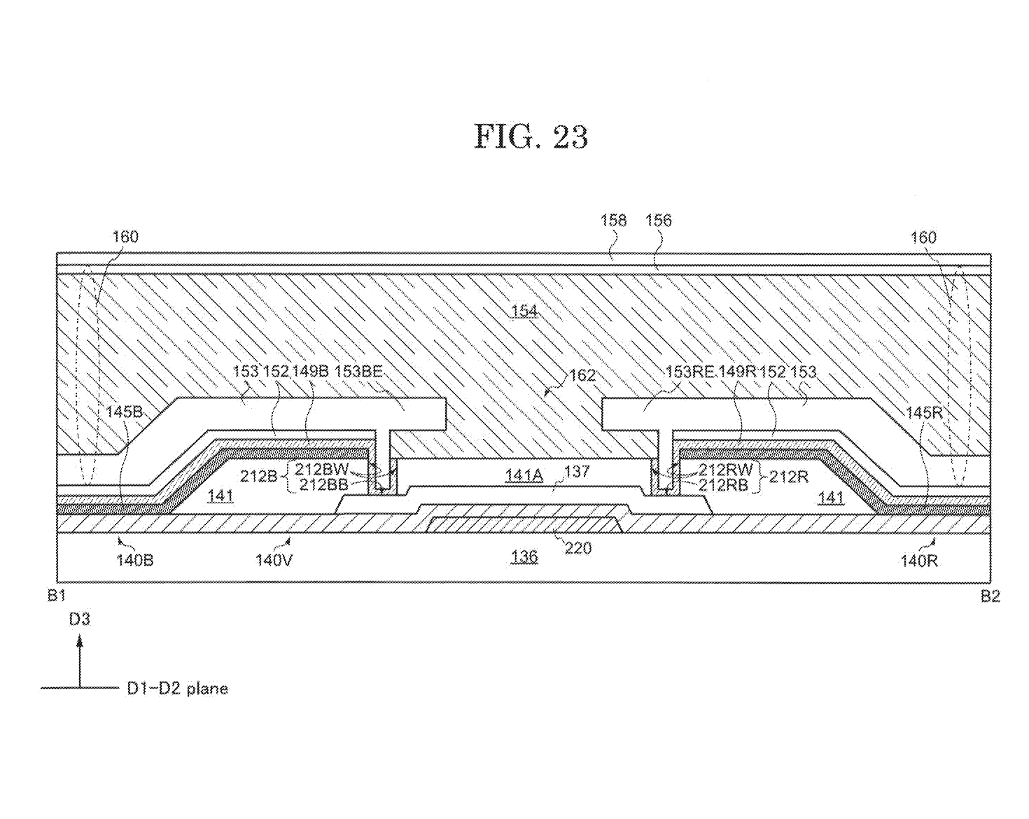

An overview of the configuration of the pixel 115 according to the third embodiment will be described with reference to FIG. 20 to FIG. 23. FIG. 20 to FIG. 22 are layout diagrams showing an example of the configuration of the pixel 115 according to the third embodiment. FIG. 23 is a cross-sectional view showing a structure of a cross-section taken along a line C1-C2 of the pixel shown in FIG. 22. Configurations that are the same as or similar to those in FIG. 1 to FIG. 19 will be described as necessary.

The pixel 115 shown in FIG. 20 is different from the pixel 115 shown in FIG. 2 in the widths of the common electrode line 140HF and the common electrode line 140V. Specifically, a width W7 of the common electrode line 140HF and the common electrode line 140V in the pixel 115 shown in FIG. 20 is wider (thicker) than the width W6 of the common electrode line 140HF and the common electrode line 140V in the pixel 115 shown in FIG. 2. By increasing the width of the common electrode line 140HF and the common electrode line 140V, the resistance values of the common electrode line 140HF and the common electrode line 140V in the pixel 115 shown in FIG. 20 can be made smaller than the resistance values of the common electrode line 140HF and the common electrode line 140V in the pixel 115 shown in FIG. 2. As a result, since the common electrode line 140HF and the common electrode line 140V can supply a stable potential to the common electrode 140, fluctuations, voltage drops, and the like in the potential supplied to the common electrode 140 are suppressed.

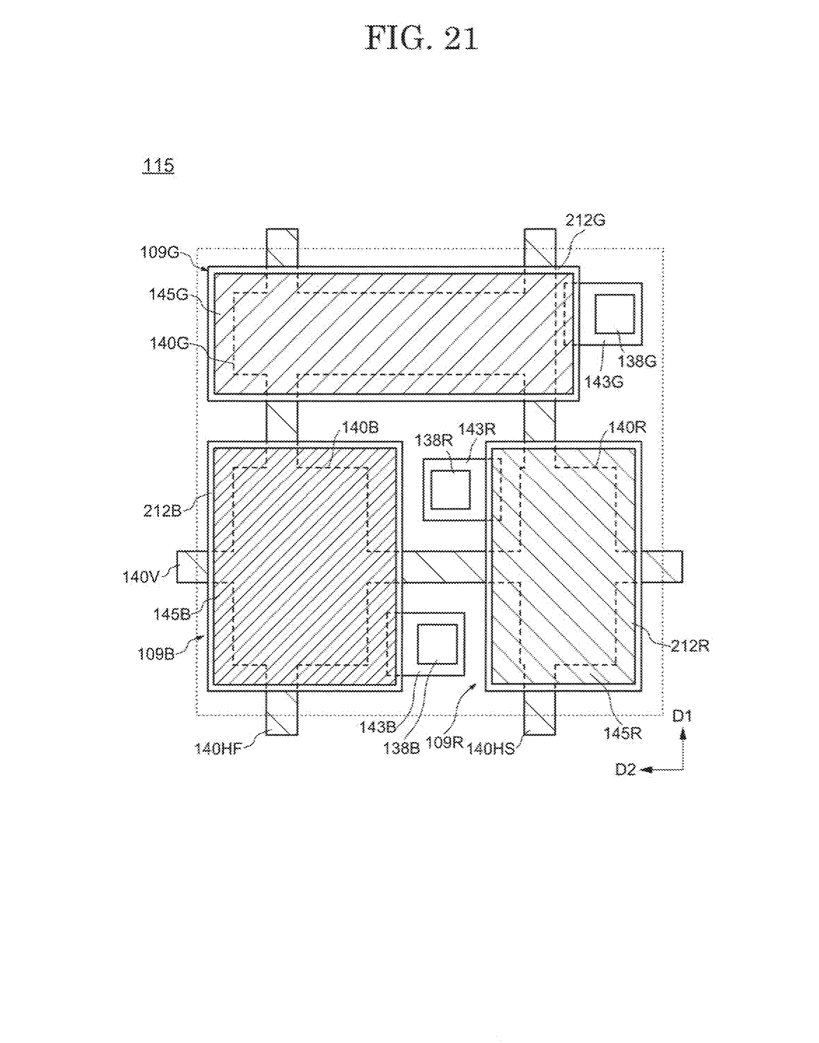

A common electrode line 140HS is added to the pixel 115 shown in FIG. 21 compared with the pixel 115 shown in FIG. 2. Specifically, the common electrode line 140HS is provided along an imaginary line parallel to the first direction D1 and is connected to the common electrode 140R and the common electrode 140G. As a result, similar to the pixel 115 shown in FIG. 20, the resistance value of the common electrode line in the pixel 115 shown in FIG. 21 can be made smaller than the resistance value of the common electrode line in the pixel 115 shown in FIG. 2. Therefore, since the common electrode line can supply a stable potential to the common electrode 140, fluctuations, voltage drops, and the like in the potential supplied to the common electrode 140 are suppressed.

The pixel 115 shown in FIG. 22 includes a conductive layer 220 stacked with the common electrode line 140HF and the common electrode line 140V, compared with the pixel 115 shown in FIG. 2. Specifically, the common electrode line 140HF and the common electrode line 140V in the pixel 115 shown in FIG. 22 include the conductive layer 220 stacked with the common electrode line 140HF and the common electrode line 140V between the grooves 212 (the grooves 212R, 212G, and 212B) of each pixel. For example, as shown in FIG. 23, the conductive layer 220 is provided between the common electrode 140V and the insulating layer 136 to be in contact with the common electrode 140V and the insulating layer 136. As a result, since the thickness of the common electrode line 140HF and the common electrode line 140V increases along the imaginary line parallel to the third direction D3 of the common electrode line 140HF and the common electrode line 140V, the resistance values of the common electrode line 140HF and the common electrode line 140V can be made smaller than the resistance value of the common electrode line in the pixel 115 shown in FIG. 2. Therefore, since the common electrode line in the pixel 115 shown in FIG. 22 can supply a stable potential to the common electrode 140, fluctuations, voltage drops, and the like in the potential supplied to the common electrode 140 are suppressed.

Although not shown, the common electrode line 140HF and the common electrode line 140V may be formed in a solid shape (plate shape) including the common electrode 140R, the common electrode 140G, and the common electrode 140B to be spaced apart from the pixel electrode 143 in a plan view. As a result, the resistance value of the common electrode line can be further reduced, so that fluctuations, voltage drops, and the like in the potential supplied to the common electrode 140 are further suppressed.

The embodiments or a part of the embodiments described above as an embodiment of the present invention can be appropriately combined and implemented as long as no contradiction is caused.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. An organic electro-luminescence display device including a plurality of pixels arranged in a first direction and a second direction intersecting the first direction,
each of the plurality of pixels comprising:
a first electrode;
a first insulating layer arranged on the first electrode;
a first inorganic insulating layer arranged on the first insulating layer;
a second electrode arranged on the first insulating layer, and including a first part provided apart from the first inorganic insulating layer and a second part overlapping and in contact with the first inorganic insulating layer;
an opening part arranged in the first insulating layer and the first inorganic insulating layer, and including a side surface of the first inorganic insulating layer, a side surface of the first insulating layer, and a first bottom part extending to the side surface of the first insulating layer and exposing a part of the surface of the first electrode;
a third electrode arranged on the first inorganic insulating layer, and in contact with the first inorganic insulating layer, the side surface of the first inorganic insulating layer, the side surface of the first insulating layer, and the first electrode at the first bottom part;
an electro-luminescence element arranged on and in contact with the first part;
a second insulating layer arranged above the electro-luminescence element, the first part, the first insulating layer excluding an area where the first part and the first inorganic insulating layer are provided, between the first inorganic insulating layer except an area where the third electrode is provided and the third electrode, on the third electrode and the opening part, and on the second part excluding an area where the third electrode is provided;
a first groove arranged in the second insulating layer, and including a side surface of the second insulating layer and a second bottom part extending to the side surface of the second insulating layer and exposing a part of the surface of the third electrode; and
a fourth electrode arranged on the electro-luminescence element and in contact with the electro-luminescence element, the side surface of the second insulating layer, and the third electrode at the second bottom part;
wherein the first bottom part is arranged in a position deeper from the top surface of the second insulating layer than the second bottom part.

2. The organic electro-luminescence display device according to claim 1, wherein the width of the first bottom part is wider than the width of the second bottom part.

3. The organic electro-luminescence display device according to claim 1, further comprising:
a third insulating layer arranged on the fourth electrode; and
a fifth inorganic insulating layer arranged on the third insulating layer and in a second groove provided in the fourth electrode.

4. The organic electro-luminescence display device according to claim 3, wherein the electro-luminescence element and the third insulating layer are provided spaced apart from the first bottom part and the second bottom part.

5. The organic electro-luminescence display device according to claim 3, wherein the fifth inorganic insulating layer includes an overhang part, the overhang part extending in the second direction from the first groove in a cross-sectional view.

6. The organic electro-luminescence display device according to claim 3, wherein each of the plurality of pixels includes a first subpixel, a second subpixel, and a third subpixel.

7. The organic electro-luminescence display device according to claim 6, wherein the electro-luminescence element of the first subpixel, the electro-luminescence element of the second subpixel, and the electro-luminescence element of the third subpixel emit light of different colors from each other, are surrounded by the different first groove and the different second groove from each other, and are spaced apart from each other.

8. The organic electro-luminescence display device according to claim 6, further comprising an organic insulating layer,
wherein the second insulating layer is provided between the first groove of the first subpixel and the first groove of the second subpixel,
the overhang part of the first subpixel is provided spaced apart from the overhang part of the second subpixel and
the organic insulating layer is provided in a space between the overhang part of the first subpixel, the overhang part of the second subpixel, and the second insulating layer between the first groove of the first subpixel and the first groove of the second subpixel, and on the fifth inorganic insulating layer.

9. The organic electro-luminescence display device according to claim 1, wherein the second part connects the second electrodes of adjacent pixels.

10. The organic electro-luminescence display device according to claim 1, further comprising a conductive layer,
wherein the conductive layer is provided on the side of the second part opposite the side on which the first inorganic insulating layer is provided.

11. A method for manufacturing an organic electro-luminescence display device including plurality of pixels arranged in a first direction and a second direction intersecting the first direction,
each of the plurality of pixels comprising:
a first electrode;
a first insulating layer arranged on the first electrode;
a first inorganic insulating layer arranged on the first insulating layer;
a second electrode arranged on the first insulating layer, and including a first part provided apart from the first inorganic insulating layer and a second part overlapping and in contact with the first inorganic insulating layer;
an opening part arranged in the first insulating layer and the first inorganic insulating layer, and including a side surface of the first inorganic insulating layer, a side surface of the first insulating layer, and a first bottom part extending to the side surface of the first insulating layer and exposing a part of the surface of the first electrode;
a third electrode arranged on the first inorganic insulating layer, and in contact with the first inorganic insulating layer, the side surface of the first inorganic insulating layer, the side surface of the first insulating layer, and the first electrode at the first bottom part;
an electro-luminescence element arranged on and in contact with the first part;
a second insulating layer arranged above the electro-luminescence element, the first part, the first insulating layer excluding an area where the first part and the first inorganic insulating layer are provided, between the first inorganic insulating layer except an area where the third electrode is provided and the third electrode, on the third electrode and the opening part, and on the second part excluding an area where the third electrode is provided;
a first groove arranged in the second insulating layer, and including a side surface of the second insulating layer and a second bottom part extending to the side surface of the second insulating layer and exposing a part of the surface of the third electrode; and
a fourth electrode arranged on the electro-luminescence element and in contact with the electro-luminescence element, the side surface of the second insulating layer, and the third electrode at the second bottom part;
wherein the first bottom part is arranged in a position deeper from the top surface of the second insulating layer than the second bottom part, and
the method comprising:
forming a second inorganic insulating layer on the second electrode where the second insulating layer is not arranged and on the second insulating layer;
forming a third inorganic insulating layer on the second inorganic insulating layer overlapping a part of the third electrode and the second insulating layer;
forming a fourth inorganic insulating layer on the second inorganic insulating layer where the third inorganic insulating layer is not provided and on the side surface and top surface of the third inorganic insulating layer;
forming a sidewall by removing the fourth inorganic insulating layer on the second inorganic insulating layer where the third inorganic insulating layer is not provided, the fourth inorganic insulating layer on the top surface, and a part of the fourth inorganic insulating layer on the side surfaces; and
forming the first groove using the sidewall.

12. The method for manufacturing an organic electro-luminescence display device according to claim 11,
wherein forming the first groove using the sidewall includes
removing the third inorganic insulating layer after forming the sidewall,
applying a first resist onto the second inorganic insulating layer excluding the second inorganic insulating layer on which the sidewall is formed,
removing the sidewall,
removing the second inorganic insulating layer exposed by removing the sidewall,
removing the second insulating layer exposed by removing the second inorganic insulating layer, and
exposing a part of the third electrode by removing the second insulating layer.

13. The method for manufacturing an organic electro-luminescence display device according to claim 12, further comprising:
after forming the first groove,
applying a second resist onto a part of the second insulating layer;
forming the electro-luminescence element on the second electrode excluding the part of the second electrode on which the second insulating layer is provided and on the second insulating layer excluding the part of the second insulating layer on which the second resist is applied;
connecting a part of the flat part of the second electrode to a part of the electro-luminescence element;
forming the fourth electrode on the electro-luminescence element, on the side surface of the second insulating layer, and on the second bottom part;
connecting the fourth electrode to the exposed part of the third electrode;
forming the fourth electrode to form a second groove;
forming a third insulating layer on the fourth electrode; and
forming a fifth inorganic insulating layer inside the second groove and on the third insulating layer.

14. The method for manufacturing an organic electro-luminescence display device according to claim 13,
wherein forming the EL element includes forming the EL element at a distance from the third electrode, and forming the third insulating layer includes forming the third insulating layer at a distance from the third electrode.

15. The method for manufacturing an organic electro-luminescence display device according to claim 14, further comprising:
after forming the fifth inorganic insulating layer,
applying a third resist onto the fifth inorganic insulating layer;
removing the fifth inorganic insulating layer except a part of the fifth inorganic insulating layer overlapping the third resist;
removing the third insulating layer extending in the first and second directions from the fifth inorganic insulating layer formed in the second groove;
removing the fourth electrodes extending in the first and second directions from the fifth inorganic insulating layer formed in the second groove except for the fourth electrode between the second insulating layer and the second groove;
removing the electro-luminescence elements extending in the first and second directions from the fifth inorganic insulating layer formed in the second groove; and
forming an overhang.

16. The method for manufacturing an organic electro-luminescence display device according to claim 15,
wherein the first groove and the second groove are formed to surround the electro-luminescence element.

17. The method for manufacturing an organic electro-luminescence display device according to claim 14, further comprising:
forming an organic insulating layer in a space between the overhang part and the second insulating layer provided below the overhang part, and on the fifth inorganic insulating layer.

18. The method for manufacturing an organic electro-luminescence display device according to claim 11, further comprising:
forming the first electrode;
forming a first insulating layer on the first electrode;
forming an opening on the first insulating layer, the opening including a side surface of the first insulating layer and a first bottom part extending to the side surface of the first insulating layer and exposing a part of the surface of the first electrode;
forming the third electrode in contact with the first insulating layer, the side surface of the first insulating layer, and the first electrode of the first bottom; and
forming the first inorganic insulating layer on the first insulating layer, spaced apart from the second electrode;
wherein the first bottom part is arranged in a position deeper from the top surface of the second insulating layer than the second bottom part.

19. The method for manufacturing an organic electro-luminescence display device according to claim 12,
wherein the width of the first bottom part is wider than the width of the second bottom part.
